(19) United States
(12) Patent Application Publication
(10) Pub. No.: US 2026/0155192 A1
(43) Pub. Date: Jun. 4, 2026

(54) STACKED MEMORY ASSEMBLY WITH FAILURE DETECTION AND REPAIR

(71) Applicant: Sandisk Technologies, Inc., Milpitas, CA (US)

(72) Inventors: Jayavel Pachamuthu, San Jose, CA (US); Jagdish Sabde, Fremont, CA (US); Rama Shukla, Saratoga, CA (US)

(73) Assignee: Sandisk Technologies, Inc., Milpitas, CA (US)

(21) Appl. No.: 18/966,178

(22) Filed: Dec. 3, 2024

(51) Int. Cl. G11C 29/10

(52) U.S. Cl. CPC G11C 29/10

(57) ABSTRACT

An apparatus includes control circuits configured to connect to stacked integrated memory assemblies through Deep Trench Contacts (DTCs) that extend through the stacked integrated memory assemblies. Each integrated memory assembly is formed of a memory die bonded to a control die. The control circuits are configured to apply a test pattern to the DTCs to detect defects in the DTCs.

### BACKGROUND

The present disclosure relates to non-volatile memory.

Semiconductor memory is widely used in various electronic devices such as cellular telephones, digital cameras, personal digital assistants, medical electronics, mobile computing devices, servers, solid state drives, non-mobile computing devices and other devices. Semiconductor memory may comprise non-volatile memory or volatile memory. Non-volatile memory allows information to be stored and retained even when the non-volatile memory is not connected to a source of power (e.g., a battery).

A memory structure in the memory system typically contains many memory cells and various control lines. The memory structure may be three-dimensional (3D). One type of 3D memory structure has non-volatile memory cells arranged as vertical NAND strings (where “vertical” is defined with respect to a substrate on which the 3D memory structure is formed).

A memory system may have control circuits to operate the memory structure (e.g., to perform memory access operations including read, write and erase operations). Some or all control circuits may be located on a separate die (e.g., a memory structure may be located on one or more memory dies and control circuits may be located on one or more additional dies). In some cases multiple dies may be combined (e.g., stacked) to form a larger assembly. Electrical conductors may be used to connect different dies in such an assembly. Failure of such electrical conductors (e.g., due to a discontinuity in a conductor or short circuit) may have undesirable consequences.

### BRIEF DESCRIPTION OF THE DRAWINGS

Like-numbered elements refer to common components in the different figures.

FIG. 1 is a block diagram depicting one embodiment of a storage system.

FIG. 2A is a block diagram of one embodiment of a memory die.

FIG. 2B is a block diagram of one embodiment of a memory assembly.

FIGS. 3A and 3B depict different embodiments of memory assemblies.

FIG. 3C illustrates a stacked memory assembly with Deep Trench Contacts (DTCs).

FIG. 4 is a perspective view of a portion of one example embodiment of a monolithic three-dimensional memory structure.

FIG. 5 shows an example of an integrated memory assembly in cross section.

FIG. 6 shows an example of a mirrored die pair formed of two integrated memory assemblies.

FIG. 7 shows a portion of a mirrored die pair in cross section.

FIGS. 8A-B show an example of a stack of mirrored die pairs.

FIG. 9 shows an example of Deep Trench Contacts (DTCs) in a stack of mirrored die pairs.

FIG. 10 shows an example of a method that includes DTC remapping.

FIGS. 11A-B show an example of testing DTCs for continuity.

FIGS. 12A-C show an example of testing DTCs using charge pump clock frequency.

FIGS. 13A-B show an example of testing DTCs for electrical shorts.

FIG. 14A shows an example of replacing DTCs.

FIG. 14B shows an example of replacing TSVs.

FIGS. 15A-C show example multiplexer/demultiplexer circuits and their operation.

FIGS. 16A-D show examples of multiplexer/demultiplexer circuits and their operation in different configurations.

FIG. 17 shows an example of multiplexer/demultiplexer circuits connected to various structures for DTC remapping.

FIG. 18 shows an example of multiplexer/demultiplexer circuits and corresponding logic circuits.

FIG. 19 shows an example of a method that includes detecting defective DTCs.

### DETAILED DESCRIPTION

Dies in a stack may be connected by Deep Trench Contacts (DTCs) that extend through the dies, with an individual DTC including multiple Through Silicon Vias (TSVs) connected in series. Technology is disclosed herein for detection and replacement of defective DTCs that extend through stacked dies (e.g., through stacked memory and control dies in a stacked memory assembly). For example, one or more voltage patterns (test patterns) may be applied to DTCs to identify defective DTCs. Redundant DTCs may be provided to enable replacement of defective DTCs with redundant DTCs. Multiplexer/demultiplexer circuits may be provided in dies of a stack to enable remapping of signals to bypass portions of a DTC (e.g., one or more TSVs). Testing may bypass different portions of a DTC to identify where a defect is located. Subsequently, multiplexer/demultiplexer circuits may reroute signals around defective portions (e.g., remapping may be used for test purposes and a remapping that overcomes a defect may be implement during operation). Appropriate logic circuits may be provided to control multiplexer/demultiplexer circuits during testing and subsequently during operation to locate and overcome defects in DTCs.

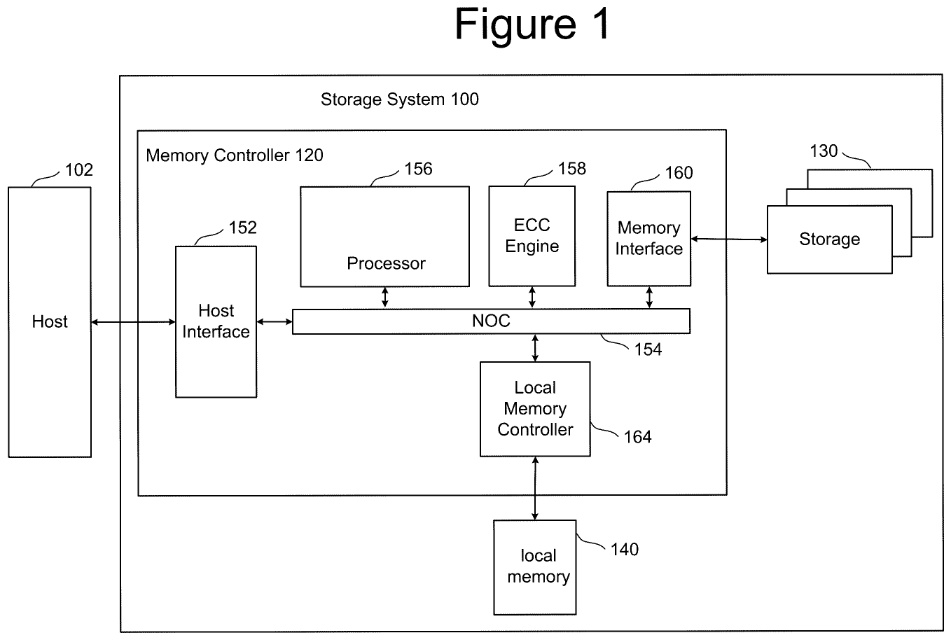

FIG. 1 is a block diagram of one embodiment of a storage system 100 that implements the technology described herein. In one embodiment, storage system 100 is a solid state drive (“SSD”). Storage system 100 can also be a memory card, USB drive or other type of storage system. The proposed technology is not limited to any one type of storage system. Storage system 100 is connected to host 102, which can be a computer, server, electronic device (e.g., smart phone, tablet or other mobile device), appliance, or another apparatus that uses memory and has data processing capabilities. In some embodiments, host 102 is separate from, but connected to, storage system 100. In other embodiments, storage system 100 is embedded within host 102.

The components of storage system 100 depicted in FIG. 1 are electrical circuits. Storage system 100 includes a memory controller 120 (or storage controller) connected to non-volatile storage 130 and local high speed memory 140 (e.g., DRAM, SRAM, MRAM). Local memory 140 is non-transitory memory, which may include volatile memory or non-volatile memory. Local high speed memory 140 is used by memory controller 120 to perform certain operations. For example, local high speed memory 140 may store logical to physical address translation tables (“L2P tables”).

Memory controller 120 comprises a host interface 152 that is connected to and in communication with host 102. In one embodiment, host interface 152 implements an NVM Express (NVMe) over PCI Express (PCIe). Other interfaces can also be used, such as SCSI, SATA, etc. Host interface 152 is also connected to a network-on-chip (NOC) 154. A NOC is a communication subsystem on an integrated circuit. NOC's can span synchronous and asynchronous clock domains or use unclocked asynchronous logic. NOC technology applies networking theory and methods to on-chip communications and brings notable improvements over conventional bus and crossbar interconnections. NOC improves the scalability of systems on a chip (SoC) and the power efficiency of complex SoCs compared to other designs. The wires and the links of the NOC are shared by many signals. A high level of parallelism is achieved because all links in the NOC can operate simultaneously on different data packets. Therefore, as the complexity of integrated subsystems keep growing, a NOC provides enhanced performance (such as throughput) and scalability in comparison with previous communication architectures (e.g., dedicated point-to-point signal wires, shared buses, or segmented buses with bridges). In other embodiments, NOC 154 can be replaced by a bus.

Connected to and in communication with NOC 154 is processor 156, ECC engine 158, memory interface 160, and local memory controller 164. Local memory controller 164 is used to operate and communicate with local high speed memory 140 (e.g., DRAM, SRAM, MRAM).

ECC engine 158 performs error correction services. For example, ECC engine 158 performs data encoding and decoding. In one embodiment, ECC engine 158 is an electrical circuit programmed by software. For example, ECC engine 158 can be a processor that can be programmed. In other embodiments, ECC engine 158 is a custom and dedicated hardware circuit without any software. In another embodiment, the function of ECC engine 158 is implemented by processor 156.

Processor 156 performs the various controller memory operations, such as programming, erasing, reading, and memory management processes. In one embodiment, processor 156 is programmed by firmware. In other embodiments, processor 156 is a custom and dedicated hardware circuit without any software. Processor 156 also implements a translation module, as a software/firmware process or as a dedicated hardware circuit. In many systems, the non-volatile memory is addressed internally to the storage system using physical addresses associated with the one or more memory die. However, the host system will use logical addresses to address the various memory locations. This enables the host to assign data to consecutive logical addresses, while the storage system is free to store the data as it wishes among the locations of the one or more memory die. To implement this system, memory controller 120 (e.g., the translation module) performs address translation between the logical addresses used by the host and the physical addresses used by the memory die. One example implementation is to maintain tables (i.e. the L2P tables mentioned above) that identify the current translation between logical addresses and physical addresses. An entry in the L2P table may include an identification of a logical address and corresponding physical address. Although logical address to physical address tables (or L2P tables) include the word “tables” they need not literally be tables. Rather, the logical address to physical address tables (or L2P tables) can be any type of data structure. In some examples, the memory space of a storage system is so large that the local memory 140 cannot hold all of the L2P tables. In such a case, the entire set of L2P tables are stored in a non-volatile storage 130 and a subset of the L2P tables are cached (L2P cache) in the local high speed memory 140.

Memory interface 160 communicates with non-volatile storage 130. In one embodiment, memory interface 160 provides a Toggle Mode interface. Other interfaces can also be used. In some example implementations, memory interface 160 (or another portion of memory controller 120) implements a scheduler and buffer for transmitting data to and receiving data from one or more memory die.

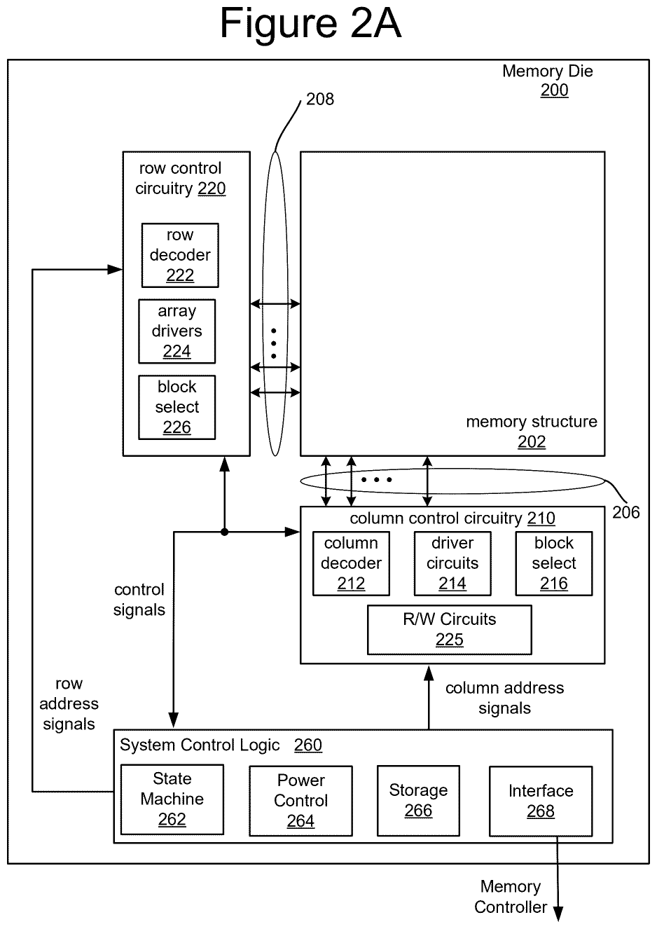

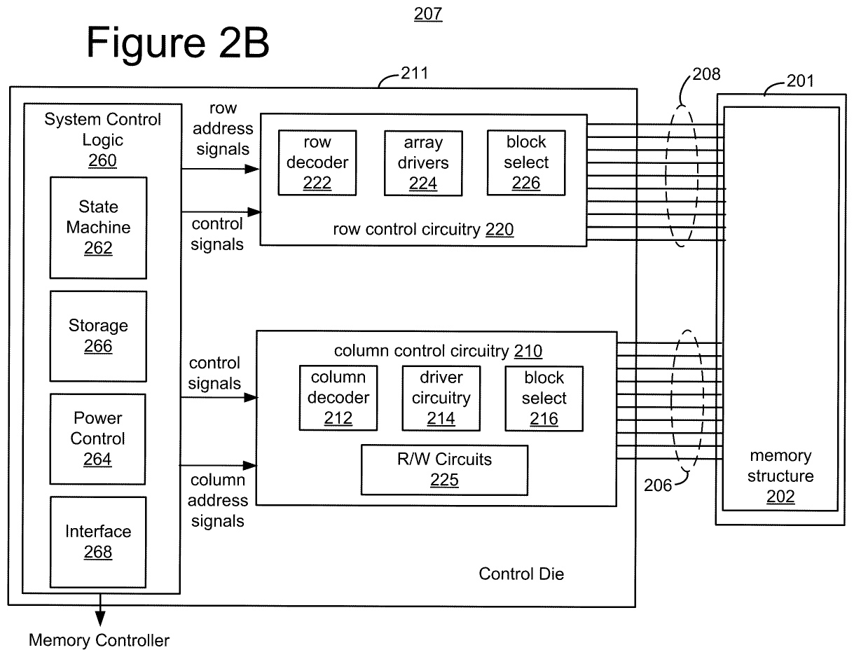

In one embodiment, non-volatile storage 130 comprises one or more memory dies. FIG. 2A is a functional block diagram of one embodiment of a memory die 200 that comprises non-volatile storage 130. Each of the one or more memory dies of non-volatile storage 130 can be implemented as memory die 200 of FIG. 2A. The components depicted in FIG. 2A are electrical circuits. Memory die 200 includes a memory structure 202 (e.g., memory array) that can comprise non-volatile memory cells (also referred to as non-volatile storage cells), as described in more detail below. The array terminal lines of memory structure 202 include the various layer(s) of word lines organized as rows, and the various layer(s) of bit lines organized as columns. However, other orientations can also be implemented. Memory die 200 includes row control circuitry 220, whose outputs are connected to respective word lines of the memory structure 202. Row control circuitry 220 receives a group of M row address signals and one or more various control signals from System Control Logic 260, and typically may include such circuits as row decoders 222, array drivers 224, and block select circuit 226 for both reading and writing (programming) operations. Row control circuitry 220 may also include read/write circuitry. Memory die 200 also includes column control circuitry 210 including read/write circuits 225. The read/write circuits 225 may contain sense amplifiers and data latches. The sense amplifier(s) input/outputs are connected to respective bit lines of the memory structure 202. Although only a single block is shown for memory structure 202, a memory die can include multiple arrays that can be individually accessed. Column control circuitry 210 receives a group of N column address signals and one or more various control signals from System Control Logic 260, and typically may include such circuits as column decoders 212, array terminal receivers or driver circuits 214, block select circuit 216, as well as read/write circuitry, and I/O multiplexers.

System control logic 260 receives data and commands from memory controller 120 and provides output data and status to the host. In some embodiments, the system control logic 260 (which comprises one or more electrical circuits) includes state machine 262 that provides die-level control of memory operations. In one embodiment, the state machine 262 is programmable by software. In other embodiments, the state machine 262 does not use software and is completely implemented in hardware (e.g., electrical circuits). In another embodiment, the state machine 262 is replaced by a micro-controller or microprocessor, either on or off the memory chip. System control logic 260 can also include a power control module 264 that controls the power and voltages supplied to the rows and columns of the memory structure 202 during memory operations. System control logic 260 includes storage 266 (e.g., RAM, registers, latches, etc.), which may be used to store parameters for operating the memory structure 202.

Commands and data are transferred between memory controller 120 and memory die 200 via memory controller interface 268 (also referred to as a “communication interface”). Memory controller interface 268 is an electrical interface for communicating with memory controller 120. Examples of memory controller interface 268 include a Toggle Mode Interface and an Open NAND Flash Interface (ONFI). Other I/O interfaces can also be used.

In some embodiments, all the elements of memory die 200, including the system control logic 260, can be formed as part of a single die. In other embodiments, some or all of the system control logic 260 can be formed on a different die than the die that contains the memory structure 202.

In one embodiment, memory structure 202 comprises a three-dimensional memory array of non-volatile memory cells in which multiple memory levels are formed above a single substrate, such as a wafer. The memory structure may comprise any type of non-volatile memory that are monolithically formed in one or more physical levels of memory cells having an active area disposed above a silicon (or other type of) substrate. In one example, the non-volatile memory cells comprise vertical NAND strings with charge-trapping layers.

In another embodiment, memory structure 202 comprises a two-dimensional memory array of non-volatile memory cells. In one example, the non-volatile memory cells are NAND flash memory cells utilizing floating gates. Other types of memory cells (e.g., NOR-type flash memory) can also be used.

The exact type of memory array architecture or memory cell included in memory structure 202 is not limited to the examples above. Many different types of memory array architectures or memory technologies can be used to form memory structure 202. No particular non-volatile memory technology is required for purposes of the new claimed embodiments proposed herein. Other examples of suitable technologies for memory cells of the memory structure 202 include ReRAM memories (resistive random access memories), magnetoresistive memory (e.g., MRAM, Spin Transfer Torque MRAM, Spin Orbit Torque MRAM), FeRAM, phase change memory (e.g., PCM), and the like. Examples of suitable technologies for memory cell architectures of the memory structure 202 include two dimensional arrays, three dimensional arrays, cross-point arrays, stacked two dimensional arrays, vertical bit line arrays, and the like.

One example of a ReRAM cross-point memory includes reversible resistance-switching elements arranged in cross-point arrays accessed by X lines and Y lines (e.g., word lines and bit lines). In another embodiment, the memory cells may include conductive bridge memory elements. A conductive bridge memory element may also be referred to as a programmable metallization cell. A conductive bridge memory element may be used as a state change element based on the physical relocation of ions within a solid electrolyte. In some cases, a conductive bridge memory element may include two solid metal electrodes, one relatively inert (e.g., tungsten) and the other electrochemically active (e.g., silver or copper), with a thin film of the solid electrolyte between the two electrodes. As temperature increases, the mobility of the ions also increases causing the programming threshold for the conductive bridge memory cell to decrease. Thus, the conductive bridge memory element may have a wide range of programming thresholds over temperature.

Another example is magnetoresistive random access memory (MRAM) that stores data by magnetic storage elements. The elements are formed from two ferromagnetic layers, each of which can hold a magnetization, separated by a thin insulating layer. One of the two layers is a permanent magnet set to a particular polarity; the other layer's magnetization can be changed to match that of an external field to store memory. A memory device is built from a grid of such memory cells. In one embodiment for programming, each memory cell lies between a pair of write lines arranged at right angles to each other, parallel to the cell, one above and one below the cell. When current is passed through them, an induced magnetic field is created. MRAM based memory embodiments will be discussed in more detail below.

Phase change memory (PCM) exploits the unique behavior of chalcogenide glass. One embodiment uses a GeTe-Sb2Te3 super lattice to achieve non-thermal phase changes by simply changing the co-ordination state of the Germanium atoms with a laser pulse (or light pulse from another source). Therefore, the doses of programming are laser pulses. The memory cells can be inhibited by blocking the memory cells from receiving the light. In other PCM embodiments, the memory cells are programmed by current pulses. Note that the use of “pulse” in this document does not require a square pulse but includes a (continuous or non-continuous) vibration or burst of sound, current, voltage light, or other wave. These memory elements within the individual selectable memory cells, or bits, may include a further series element that is a selector, such as an ovonic threshold switch or metal insulator substrate.

A person of ordinary skill in the art will recognize that the technology described herein is not limited to a single specific memory structure, memory construction or material composition, but covers many relevant memory structures within the spirit and scope of the technology as described herein and as understood by one of ordinary skill in the art.

The elements of FIG. 2A can be grouped into two parts: (1) memory structure 202 and (2) peripheral circuitry, which includes all of the other components depicted in FIG. 2A. An important characteristic of a memory circuit is its capacity, which can be increased by increasing the area of the memory die of storage system 100 that is given over to the memory structure 202; however, this reduces the area of the memory die available for the peripheral circuitry. This can place quite severe restrictions on these elements of the peripheral circuitry. For example, the need to fit sense amplifier circuits within the available area can be a significant restriction on sense amplifier design architectures. With respect to the system control logic 260, reduced availability of area can limit the available functionalities that can be implemented on-chip. Consequently, a basic trade-off in the design of a memory die for the storage system 100 is the amount of area to devote to the memory structure 202 and the amount of area to devote to the peripheral circuitry.

Another area in which the memory structure 202 and the peripheral circuitry are often at odds is in the processing involved in forming these regions, since these regions often involve differing processing technologies and the trade-off in having differing technologies on a single die. For example, when the memory structure 202 is NAND flash, this is an NMOS structure, while the peripheral circuitry is often CMOS based. For example, elements such sense amplifier circuits, charge pumps, logic elements in a state machine, and other peripheral circuitry in system control logic 260 often employ PMOS devices. Processing operations for manufacturing a CMOS die will differ in many aspects from the processing operations optimized for an NMOS flash NAND memory or other memory cell technologies. Three-dimensional NAND structures in particular may benefit from specialized processing operations.

To improve upon these limitations, embodiments described below can separate the elements of FIG. 2A onto separately formed dies that are then bonded together. More specifically, the memory structure 202 can be formed on one die (referred to as the memory die) and some or all of the peripheral circuitry elements, including one or more control circuits, can be formed on a separate die (referred to as the control die). For example, a memory die can be formed of just the memory elements, such as the array of memory cells of flash NAND memory, MRAM memory, PCM memory, ReRAM memory, or other memory type. Some or all of the peripheral circuitry, even including elements such as decoders and sense amplifiers, can then be moved on to a separate control die. This allows each of the memory die to be optimized individually according to its technology. For example, a NAND memory die can be optimized for an NMOS based memory array structure, without worrying about the CMOS elements that have now been moved onto a control die that can be optimized for CMOS processing. This allows more space for the peripheral elements, which can now incorporate additional capabilities that could not be readily incorporated were they restricted to the margins of the same die holding the memory cell array. The two die can then be bonded together in a bonded multi-die memory circuit, with the array on the one die connected to the periphery elements on the other die. Although the following will focus on a bonded memory circuit of one memory die and one control die, other embodiments can use more die, such as two memory die and one control die, for example.

FIG. 2B shows an alternative arrangement to that of FIG. 2A which may be implemented using wafer-to-wafer bonding to provide a bonded die pair. FIG. 2B depicts a functional block diagram of one embodiment of an integrated memory assembly 207. One or more integrated memory assemblies 207 may be used to implement the non-volatile storage 130 of storage system 100. The integrated memory assembly 207 includes two types of semiconductor dies (or more succinctly, “die”). Memory structure die 201 includes memory structure 202. Memory structure 202 includes non-volatile memory cells. Control die 211 includes control circuitry 260, 210, and 220 (as described above). In some embodiments, control die 211 is configured to connect to the memory structure 202 in the memory structure die 201. In some embodiments, the memory structure die 201 and the control die 211 are bonded together.

FIG. 2B shows an example of the peripheral circuitry, including control circuits, formed in a peripheral circuit or control die 211 coupled to memory structure 202 formed in memory structure die 201. Common components are labelled similarly to FIG. 2A. System control logic 260, row control circuitry 220, and column control circuitry 210 are located in control die 211. In some embodiments, all or a portion of the column control circuitry 210 and all or a portion of the row control circuitry 220 are located on the memory structure die 201. In some embodiments, some of the circuitry in the system control logic 260 is located on the on the memory structure die 201.

System control logic 260, row control circuitry 220, and column control circuitry 210 may be formed by a common process (e.g., CMOS process), so that adding elements and functionalities, such as ECC, more typically found on a memory controller 120 may require few or no additional process steps (i.e., the same process steps used to fabricate memory controller 120 may also be used to fabricate system control logic 260, row control circuitry 220, and column control circuitry 210). Thus, while moving such circuits from a die such as memory structure die 201 may reduce the number of steps needed to fabricate such a die, adding such circuits to a die such as control die 211 may not require many additional process steps. The control die 211 could also be referred to as a CMOS die, due to the use of CMOS technology to implement some or all of control circuitry 260, 210, 220.

FIG. 2B shows column control circuitry 210 including read/write circuits 225 on the control die 211 coupled to memory structure 202 on the memory structure die 201 through electrical paths 206. For example, electrical paths 206 may provide electrical connection between column decoder 212, driver circuits 214, and block select circuit 216 and bit lines of memory structure 202. Electrical paths may extend from column control circuitry 210 in control die 211 through pads on control die 211 that are bonded to corresponding pads of the memory structure die 201, which are connected to bit lines of memory structure 202. Each bit line of memory structure 202 may have a corresponding electrical path in electrical paths 206, including a pair of bond pads, which connects to column control circuitry 210. Similarly, row control circuitry 220, including row decoder 222, array drivers 224, and block select circuit 226 are coupled to memory structure 202 through electrical paths 208. Each of electrical path 208 may correspond to a word line, dummy word line, or select gate line. Additional electrical paths may also be provided between control die 211 and memory structure die 201 (memory die).

For purposes of this document, the phrases “a control circuit” or “one or more control circuits” can include any one of or any combination of memory controller 120, state machine 262, power control module 264, all or a portion of system control logic 260, all or a portion of row control circuitry 220, all or a portion of column control circuitry 210, read/write circuits 225, sense amps, a microcontroller, a microprocessor, and/or other similar functioned circuits. A control circuit can include hardware only or a combination of hardware and software (including firmware). For example, a controller programmed by firmware to perform the functions described herein is one example of a control circuit. A control circuit can include a processor, FPGA, ASIC, integrated circuit, or other type of circuit.

For purposes of this document, the term “apparatus” can include, but is not limited to, one or more of, storage system 100, memory controller 120, non-volatile storage 130, memory die 200 201, integrated memory assembly 207, and/or control die 211 or 204.

In some embodiments, there is more than one control die 204 (e.g., configured similarly to control die 211 of FIG. 2B) and more than one memory die 200 (e.g., configured similarly to memory die 201 of FIG. 2B) in an integrated memory assembly 207. In some embodiments, the integrated memory assembly 207 includes a stack of multiple control dies 204 and multiple memory structure dies 200.

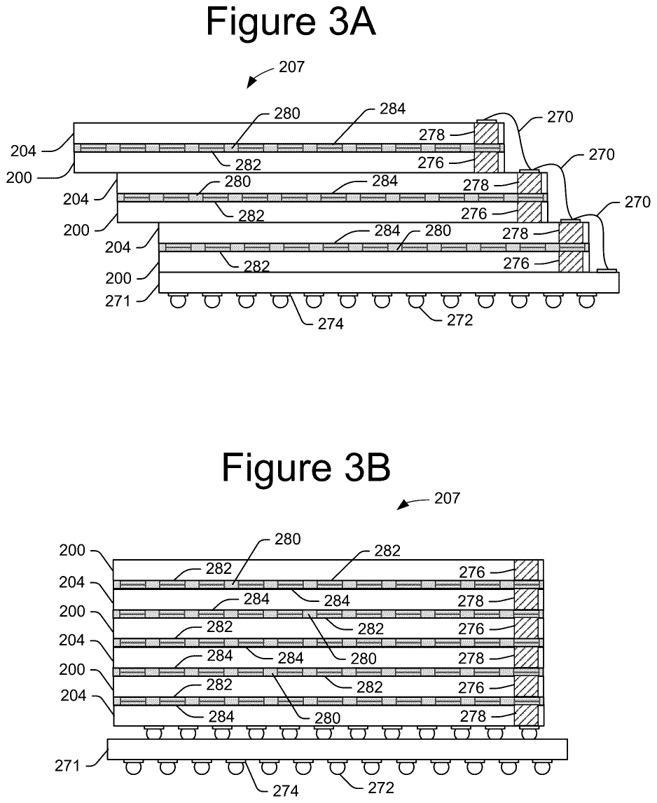

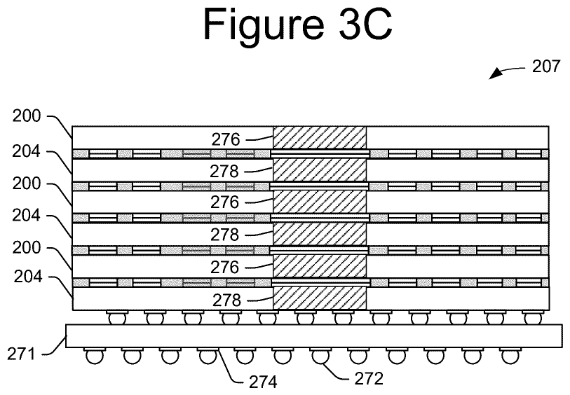

FIG. 3A depicts a side view of an embodiment of an integrated memory assembly 207 stacked on a substrate 271 (e.g., a stack comprising control die 204 and memory structure die). The integrated memory assembly 207 has three control dies 204 and three memory structure dies 200. In some embodiments, there are more than three memory structure dies 200 and more than three control dies 204. In FIG. 3A there are an equal number of memory structure dies 200 and control dies 204; however, in one embodiment, there are more memory structure dies 200 than control dies 204. For example, one control die 204 could control multiple memory structure dies 200.

Each control die 204 is affixed (e.g., bonded) to at least one of the memory structure die 200. Some of the bond pads 282/284 are depicted. There may be many more bond pads. A space between two die 200, 204 that are bonded together is filled with a solid layer 280, which may be formed from epoxy or other resin or polymer. This solid layer 280 protects the electrical connections between the die 200, 204, and further secures the die together. Various materials may be used as solid layer 280.

The integrated memory assembly 207 may for example be stacked with a stepped offset, leaving the bond pads at each level uncovered and accessible from above. Wire bonds 270 connected to the bond pads connect the control die 204 to the substrate 271. A number of such wire bonds may be formed across the width of each control die 204 (i.e., into the page of FIG. 3A).

A memory die through silicon via (TSV) 276 may be used to route signals through a memory structure die 200. A control die through silicon via (TSV) 278 may be used to route signals through a control die 204. The TSVs 276, 278 may be formed before, during or after formation of the integrated circuits in dies 200, 204. The TSVs may be formed by etching holes through the wafers. The holes may then be lined with a barrier against metal diffusion. The barrier layer may in turn be lined with a seed layer, and the seed layer may be plated with an electrical conductor such as copper, although other suitable materials such as aluminum, tin, nickel, gold, doped polysilicon, and alloys or combinations thereof may be used.

Solder balls 272 may optionally be affixed to contact pads 274 on a lower surface of substrate 271. The solder balls 272 may be used to couple the integrated memory assembly 207 electrically and mechanically to a host device such as a printed circuit board. Solder balls 272 may be omitted where the integrated memory assembly 207 is to be used as an LGA package. The solder balls 272 may form a part of the interface between integrated memory assembly 207 and memory controller 120.

FIG. 3B depicts a side view of another embodiment of an integrated memory assembly 207 stacked on a substrate 271. The integrated memory assembly 207 of FIG. 3B has three control dies 204 and three memory structure dies 200. In some embodiments, there are many more than three memory structure dies 200 and many more than three control dies 204. In this example, each control die 204 is bonded to at least one memory structure die 200. Optionally, a control die 204 may be bonded to two or more memory structure dies 200.

Some of the bond pads 282, 284 are depicted. There may be many more bond pads. A space between two dies 200, 204 that are bonded together is filled with a solid layer 280, which may be formed from epoxy or other resin or polymer. In contrast to the example in FIG. 3A, the integrated memory assembly 207 in FIG. 3B does not have a stepped offset. A memory die through silicon via (TSV) 276 may be used to route signals through a memory structure die 200. A control die through silicon via (TSV) 278 may be used to route signals through a control die 204.

Solder balls 272 may optionally be affixed to contact pads 274 on a lower surface of substrate 271. The solder balls 272 may be used to couple the integrated memory assembly 207 electrically and mechanically to a host device such as a printed circuit board. Solder balls 272 may be omitted where the integrated memory assembly 207 is to be used as an LGA package.

As has been briefly discussed above, the control die 204 and the memory structure die 200 may be bonded together. Bond pads on each die 200, 204 may be used to bond the two die together. In some embodiments, the bond pads are bonded directly to each other, without solder or other added material, in a so-called Cu-to-Cu bonding process. In a Cu-to-Cu bonding process, the bond pads are controlled to be highly planar and formed in a highly controlled environment largely devoid of ambient particulates that might otherwise settle on a bond pad and prevent a close bond. Under such properly controlled conditions, the bond pads are aligned and pressed against each other to form a mutual bond based on surface tension. Such bonds may be formed at room temperature, though heat may also be applied. In embodiments using Cu-to-Cu bonding, the bond pads may be about 5 μm square and spaced from each other with a pitch of 5 μm to 5 μm. While this process is referred to herein as Cu-to-Cu bonding, this term may also apply even where the bond pads are formed of materials other than Cu.

When the area of bond pads is small, it may be difficult to bond the semiconductor dies together. The size of, and pitch between, bond pads may be further reduced by providing a film layer on the surfaces of the semiconductor die including the bond pads. The film layer is provided around the bond pads. When the die are brought together, the bond pads may bond to each other, and the film layers on the respective die may bond to each other. Such a bonding technique may be referred to as hybrid bonding. In embodiments using hybrid bonding, the bond pads may be about 5 μm square and spaced from each other with a pitch of 1 μm to 5 μm. Bonding techniques may be used providing bond pads with even smaller sizes and pitches.

Some embodiments may include a film on surface of the dies 200, 204. Where no such film is initially provided, a space between the die may be under filled with an epoxy or other resin or polymer. The under-fill material may be applied as a liquid which then hardens into a solid layer. This under-fill step protects the electrical connections between the dies 200, 204, and further secures the die together. Various materials may be used as under-fill material.

FIG. 3C shows another example of a stacked integrated memory assembly 207 (stacked memory assembly) with center connection. While the example of FIG. 3B shows TSVs 276 and 278 located in an edge region of dies 200 and 204 respectively, FIG. 3C shows TSVs 276 and 278 located in a central region of dies 200 and 204 respectively.

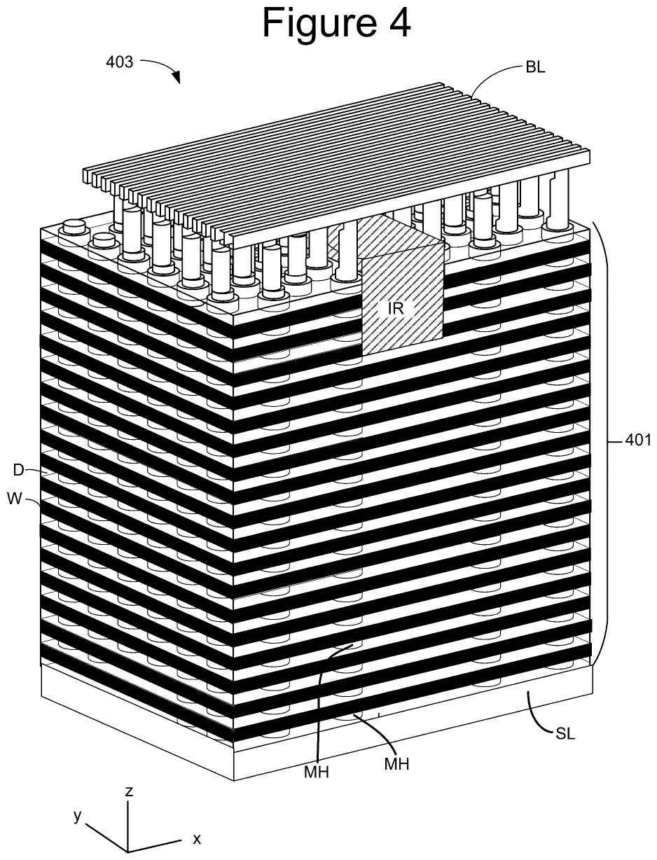

FIG. 4 is a perspective view of a portion of one example embodiment of a monolithic three dimensional memory array/structure that can comprise memory structure 202, which includes a plurality non-volatile memory cells arranged as vertical NAND strings (e.g., 3D NAND memory structure). For example, FIG. 4 shows a portion 403 of one block of memory. The structure depicted includes a set of bit lines BL positioned above a stack 401 of alternating dielectric layers and conductive layers. For example purposes, one of the dielectric layers is marked as D and one of the conductive layers (also called word line layers) is marked as W. The number of alternating dielectric layers and conductive layers can vary based on specific implementation requirements. In one embodiment the alternating dielectric layers and conductive layers are divided into four (or a different number of) regions (e.g., sub-blocks) by isolation regions IR. FIG. 4 shows one isolation region IR separating two sub-blocks. Below the alternating dielectric layers and word line layers is a source line layer SL. Memory holes are formed in the stack of alternating dielectric layers and conductive layers. For example, one of the memory holes is marked as MH. Note that in FIG. 4, the dielectric layers are depicted as see-through so that the reader can see the memory holes positioned in the stack of alternating dielectric layers and conductive layers. In one embodiment, NAND strings are formed by filling the memory hole with materials including a charge-trapping material to create a vertical column of memory cells. Each memory cell can store one or more bits of data. More details of the three dimensional monolithic memory array that comprises memory structure 202 is provided below.

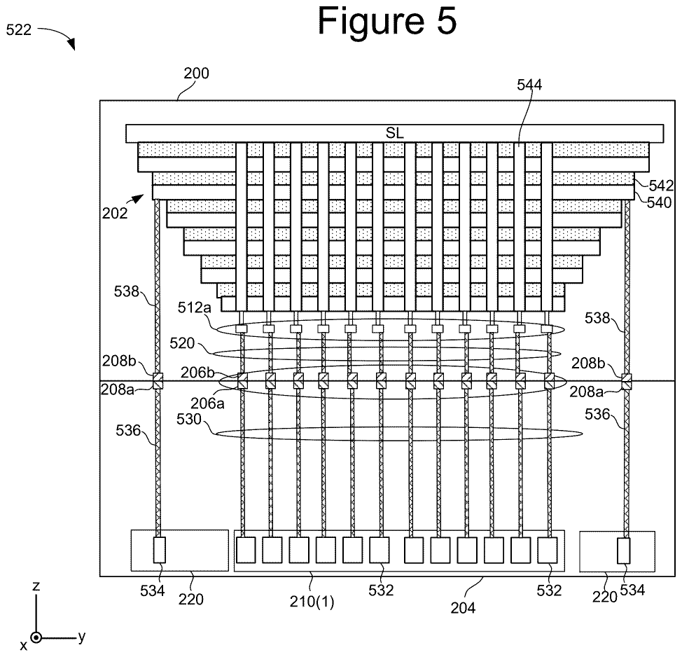

FIG. 5 depicts a control die 204 bonded to a memory die 200 to form an integrated memory assembly 522. The memory structure 202 has a stack of conductive layers 540 alternating with dielectric layers 542. NAND strings 544 are formed in the stack. The NAND strings 544 extend in the z-direction. Bit lines 512a reside in a metal layer adjacent to the stack. The control die 204 has row control circuitry 220, column control circuitry 210(1) and system control logic 260 (not shown in this view). The column control circuitry 210(1) has column circuits 532. Each column circuit 532 may include a sense amplifier and/or bit line driver. In some embodiments, the sense amplifier contains the bit line driver. Each particular column circuit 532 is electrically connected to a bit line of bit lines 512a. Each pathway includes a control die via structure 530 that connects the particular column circuit 532 to a control die bond pad 206 a. A bit line contact/via 520 connects the memory die bond pad 206 b to the bit line 512a.

FIG. 5 also depicts example connections between word line drivers 534 and the memory structure 202. The memory structure 202 has a staircase structure at two edges to allow connections to be made to conductive layers 540. The conductive layers 540 may include word lines and select lines. A word line driver 534 in the row control circuitry 220 is connected to a die bond pad 208a by way of a via structure 536. Staircase via structure 538 connects memory die bond pad 208b to a conductive layer 540. Connections from other word line drivers 534 to other conductive layers 540 are not visible in FIG. 5. Additional circuits (not shown in FIG. 5) may be present in control die 204 (e.g., some or all of the circuits shown in control die 211 of FIG. 2B). In some cases, an integrated memory assembly such as integrated memory assembly 522 may be combined with one or more additional integrated memory assemblies to form a larger assembly, which may store a large amount of data.

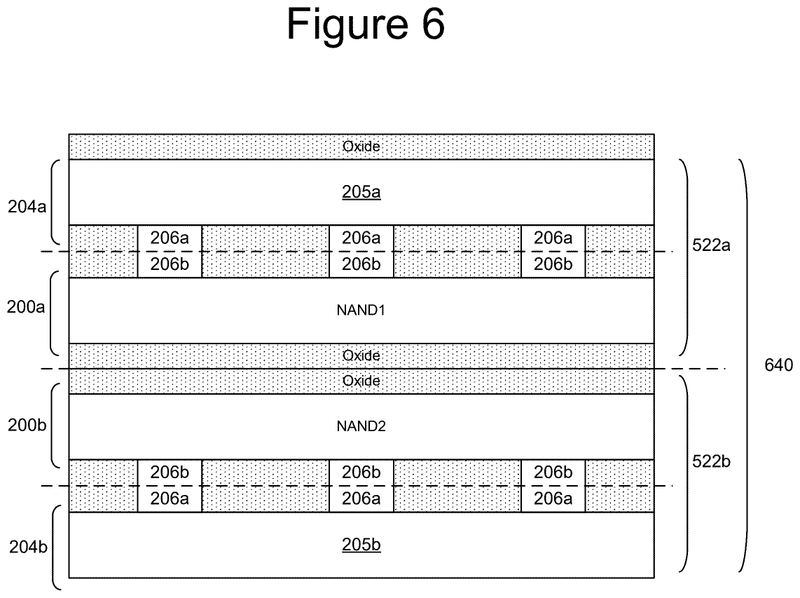

FIG. 6 illustrates an example of a first integrated memory assembly 522a, which is formed of a memory die 200 and a control die 204a (e.g., integrated memory assembly 522, formed of memory die 200 and control die 204). Control die 204a includes control circuits formed on a silicon substrate 205a. First integrated memory assembly 522a is inverted compared with integrated memory assembly 522 of FIG. 5, with control die 204a above memory die 200a. A second integrated memory assembly 522b is formed of memory die 200b and control die 204b and is located below first integrated memory assembly 522a. Control die 204b includes control circuits formed on silicon substrate 205b. Second integrated memory assembly 522b is oriented similarly to integrated memory assembly 522 in FIG. 5 so that first and second integrated memory assemblies 522a and 522b are in a mirror-image arrangement (e.g., mirror image about a plane between integrated memory assemblies 522a and 522b) and together may be considered to form a mirrored die pair 640. First and second integrated memory assemblies 522a and 522b may be bonded together (bond pads between first and second integrated memory assemblies 522a and 522b are not shown in FIG. 6). In some cases, two or more mirrored die pairs may be combined (e.g., stacked) in a single memory system (e.g., in alternating orientation such that the orientation of even numbered integrated memory assemblies is opposite to orientation of odd numbered integrated memory assemblies).

Electrical connections to dies (e.g., control and memory dies) that are arranged in a stacked configuration may pass through one or more other dies in the stack. For example, a stack of dies that are arranged to form one or more mirrored die pair may include electrical conductors that extend through portions of the stacked dies to form electrical connections between dies and/or with external components (e.g., via bond pads formed on an exterior surface of the stack such as a bottom or top surface).

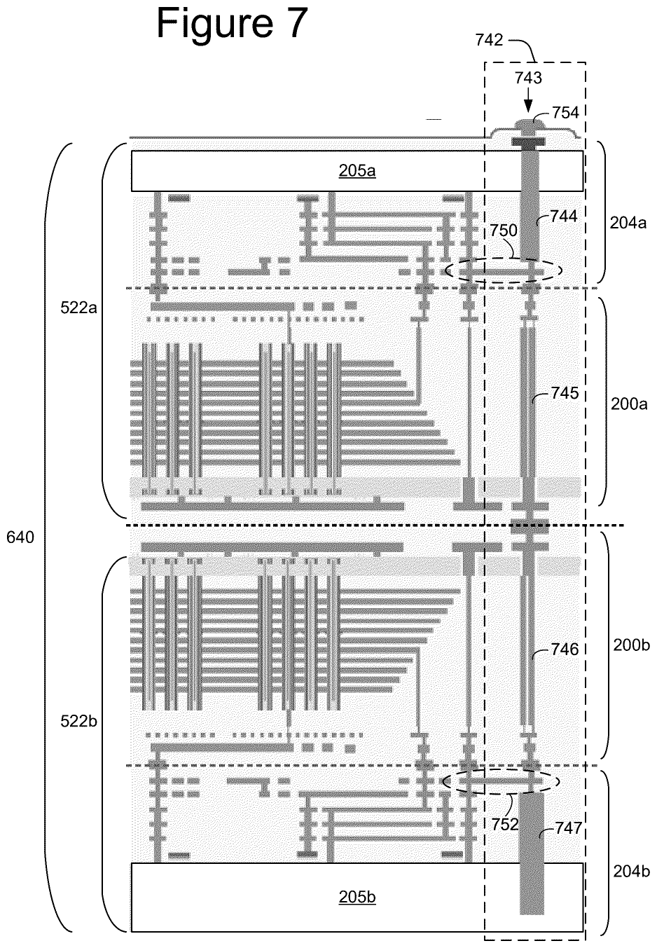

FIG. 7 illustrates an example of mirrored die pair 640, which includes a Deep Trench Contact (DTC) region 742 that extends through stacked integrated memory assemblies 522a and 522b and includes DTCs that connect between components (e.g., between integrated memory assemblies 522a, 522b and/or additional components that may be provided in the stack or adjacent to the stack). For example, FIG. 7 shows a DTC 743 that extends through the stack that forms mirrored die pair 640 and includes Through Silicon Vias (TSVs) through each of the dies of mirrored die pair 640 including TSV 744 through control die 204a (including through silicon substrate 205a), TSV 745 through memory die 200a, TSV 746 and through memory die 200b. In addition, via 747 extends into control die 204 b (including into silicon substrate 205b) although it does not extend all the way through control die 204b and may not be considered a “through Silicon” via. A DTC region may include multiple DTCs to connect components in a stack (e.g., providing supply voltages, command signals, data and address signals such as described with respect to electrical paths 206 and 208). Each DTC may include multiple vias (including, but not limited to TSVs) connected in series (e.g., by bonding between dies). For example, TSV 744, TSV 745, TSV 746 and via 747 may be connected in series by bonding of pairs of bond pads at interfaces between dies.

A DTC may be connected to electrical circuits in one or more die in a stack. For example, FIG. 7 shows DTC 743 connected to circuits of control die 200a by connection 750 (e.g., a metal wire or trace), which extends from TSV 744 in DTC region 742 and connects to one or more logic circuit of control die 200a. FIG. 7 also shows DTC 743 connected to circuits of control die 204b by connection 752, which extends from via 747 in DTC region 742 and connects to one or more logic circuit of control die 204b. DTC 743 further includes a contact pad or bump 754, which may be used to connect DTC 743 to one or more additional circuit (e.g., a circuit outside the stack of mirrored die pairs). While specific connections to control dies 200a and 200b are shown, DTCs may be connected in any desired configuration to any one or more die (e.g., control die(s) and/or memory die(s)) in order to provide desired electrical connections to provide supply voltages, commands, user data, address data and/or any other electrical signals that may be appropriate.

In some cases, two or more mirrored die pairs (e.g., mirrored die pair 640) may be combined in a stacked arrangement to form a stack of integrated memory assemblies that have alternating orientations (e.g., similar to integrated memory assemblies 522a and 522b). A DTC region may extend through such a stack and may include DTCs that enable access to memory cells in individual mirrored die pairs in the stack (e.g., by accessing memory cells in each memory die via control circuits in a corresponding control die of an integrated memory assembly).

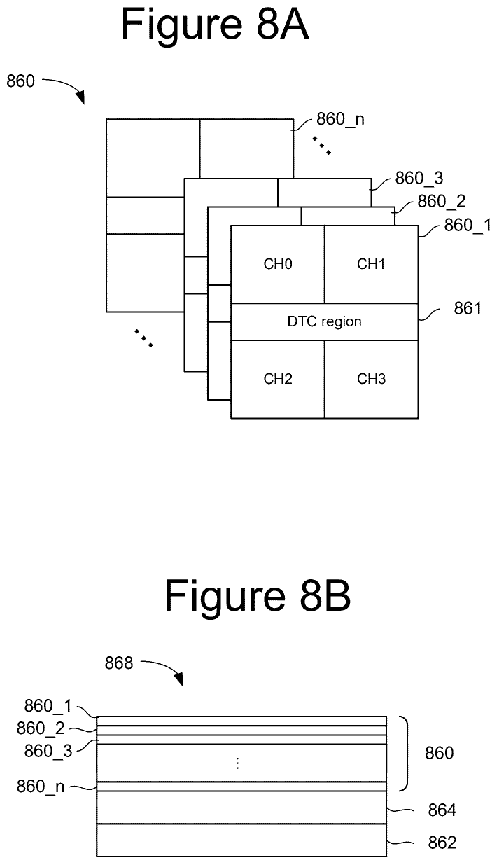

FIG. 8A shows an example of a stack 860 of mirrored die pairs 860_1 to 860_n in exploded view. The number of mirrored die pairs, n, in such a stack may be, for example, 4, 8, 16 or some other number. Each mirrored die pair may include a DTC region to enable connection of memory die pairs. For example, mirrored die pair 860_1 includes DTC region 861. On either side of DTC region 861 are areas CH0 to CH3, which correspond to four channels that may be configured to allow some degree of independent operation of each channel. In an example, memory dies in mirrored die pair 860_1 include an equal number of planes in each area CH0 to CH3 (e.g., four, eight, sixteen, thirty-two, sixty-four or some other number of planes per channel) and control dies in mirrored die pair 860_1 include corresponding control circuits in each channel area CH0 to CH3 (e.g., circuits in CH0 area of a control die are connected to planes of CH0 in the memory die that is bonded to the control die). Mirrored die pairs 860_1 to 860_n may be identical so that each mirrored die pair has a similar structure, which may be as illustrated with respect to mirrored die pair 640 or otherwise. In some cases, mirrored die pairs in a stack may differ in one or more respects. While DTC region 861 is shown at a particular location, the location and dimensions of a DTC region are not limited to the example shown (e.g., DTC region may extend along die edges). In some cases, multiple separate DTC regions may be provided.

FIG. 8B shows a side-view of stack 860, including mirrored die pairs 860_1 to 860_n and further shows a memory controller die 862, which is connected to mirrored die pairs 860_1 to 860_n through DTC regions of the stack and through DTC interface 864. For example, memory controller die 862 may include a memory controller (e.g., memory controller 120) and/or other circuits (e.g., local memory 140) so that the combination of memory controller die 862 and stack 860 may form a storage system 868 that is similar to storage system 100 and which can be connected to a host (e.g., host 102). Storage system 868 forms a compact storage system with a high data storage capacity and relatively short connections between components, which may facilitate low latency, low power consumption and/or provide other benefits. A number of DTCs may connect memory control die 862 and mirrored die pairs 860_1 to 860_n to enable memory access operations (e.g., read, write and erase).

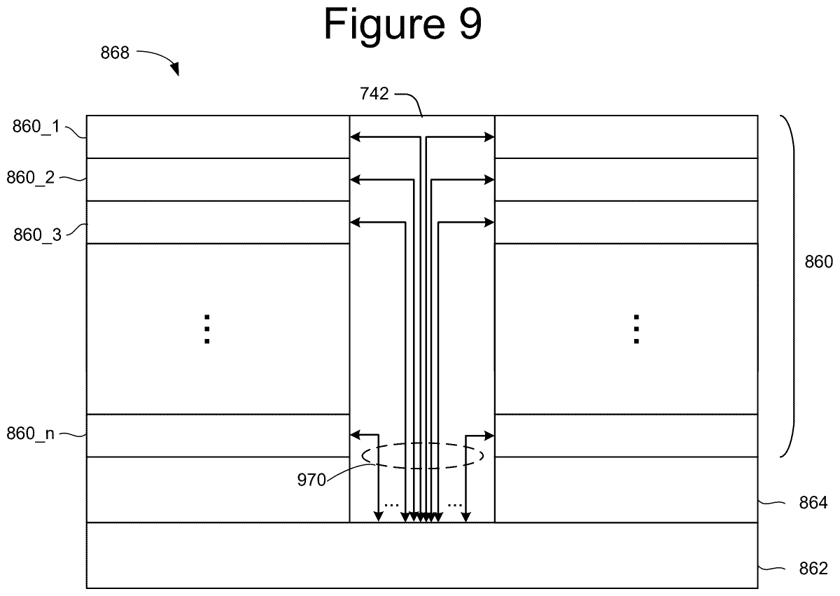

FIG. 9 provides a schematic illustration of DTCs 970 extending through DTC region 742, which extends through mirrored die pairs 860_1 to 860_n in storage system 868. DTCs 970 may connect memory control die 862 with mirrored die pairs 860_1 to 860_n and may include a number of DTCs to provide supply voltages, clock signal(s), commands, user data, address data and/or other electrical signals.

In some cases, one or more DTC may be defective so that a signal to be transferred over the DTC may not be adequately sent and/or received. Such defective DTCs may impact storage system 868. For example, when such defective DTCs are detected during testing (e.g., factory testing, prior to sale of a product) they may cause a storage system to be discarded, which may costly. When defective DTCs manifest in a product that is in use, stored data may be lost (e.g., where defective DTC(s) prevent adequate connection to a mirrored die pair or portion thereof, data stored in the mirrored die pair or portion may be unrecoverable), which may be undesirable and costly. In some cases, memory cells of a storage system (e.g., storage system 868) may be programmed to store weights, which may be used to perform in-memory vector-matrix multiplication or other operations for ML or AI applications. Obtaining weights may take significant time and resources so that the loss of such data may represent a significant loss.

Aspects of the present technology are directed to systems and methods that address technical problems of DTC failure, which may include open DTCs (e.g., electrically discontinuous DTC) short circuited DTCs (e.g., two or more DTCs electrically connected to each other and/or to other components) and/or DTCs that are otherwise defective (e.g., unable to adequately convey a signal between two or more locations in a storage system). Aspects of the present technology include technical solutions that enable detection and replacement of defective DTCs by redundant DTCs (spare or back-up DTCs). For example, a defective DTC may be replaced in whole or in part using a redundant DTC so that an electrical signal that might otherwise be sent through the defective DTC is sent through the redundant DTC and thus reaches its destination. Replacement of defective DTCs with redundant DTCs may occur during testing (e.g., factory testing) and/or when defective DTCs are encountered after some period of use (e.g., in response to some triggering event such as a read failure, a period of time of operation, a number of write-erase cycles, a number of errors above a limit and/or other triggering event).

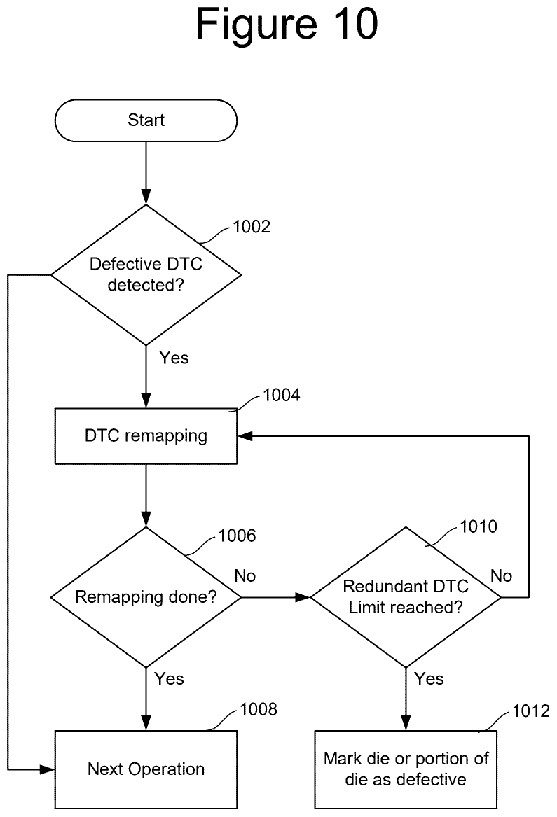

FIG. 10 illustrates an example of a method according to aspects of the present technology. The method of FIG. 10 may be applied during testing and/or at some time during the lifetime of a product. The method may be carried out by circuits configured to test and configure DTCs, which may include circuits in a memory controller and/or in other locations (e.g., in memory control dies of a stack). A determination is made as to whether any defective DTC is detected 1002 (e.g., DTCs may be tested by applying a test pattern and monitoring voltages). If no defective DTCs are detected then no further steps are needed and the next operation 1008 may be initiated (e.g., additional DTCs may be tested or some other operation may be performed). If one or more defective DTC is detected then DTC remapping 1004 is performed and a determination is made as to whether remapping is done 1006 (e.g., if all detected defective DTCs have been remapped). If remapping is done then the next operation 1008 may be initiated. If remapping is not done then a determination is made as to whether a redundant DTC limit has been reached 1010. For example, a finite number of redundant DTCs may be available for a given group of DTCs, which may impose a limit (e.g., when all the available redundant DTCs are used, additional remapping may not be possible). If the redundant DTC limit has not been reached then additional remapping may be performed (e.g., DTC remapping 1004 may be performed one DTC at a time until remapping is done or the limit is reached). If the redundant DTC limit is reached then the corresponding die or portion of the die may be marked as defective 1012. For example, defective DTCs for a given unit (e.g., block, plane, channel, memory die, mirrored die pair or other unit) may exceed the number of redundant DTCs available for the unit and as a result the unit may be marked as defective. This may mean that the unit is not subsequently used for data storage.

Testing DTCs (e.g., DTCs 970) to detect any defective DTCs (e.g. step 1002) may include one or more testing steps to detect, for example, an open DTC (e.g., electrically discontinuous), a shorted DTC (e.g., a DTC that is electrically connected to another component such as another DTC) and/or other defective DTCs.

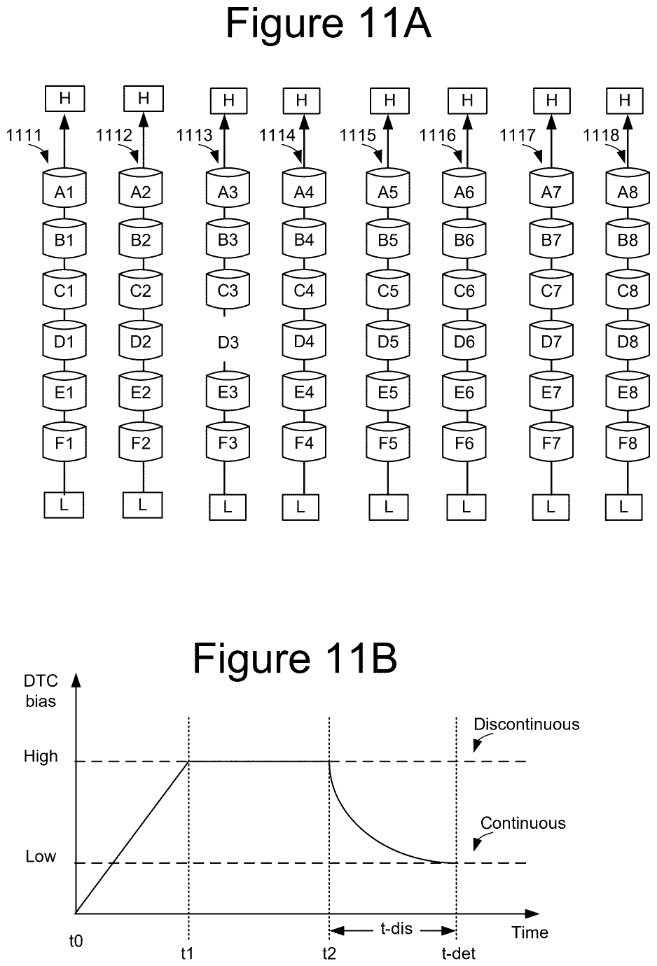

FIG. 11A illustrates an example of a group of eight DTCs 1111 to 1118 in schematic form. Each DTC includes TSVs of dies that are connected in series to form a DTC. For example, first DTC 1111 includes a first TSV, A1 (shown as a cylinder of electrically conductive material such as copper, aluminum or other metal), which may extend through a first die, a second TSV, B1, which may extend through a second die, a third TSV, C1, which may extend through a third die and so on with TSVs connected in series by pairs of bond pads at interfaces between dies. A voltage or bias may be applied at one or both ends of a DTC during a test and FIG. 11A illustrates a high voltage, “H”, applied at the top of DTCs 1111 to 1118 and a low voltage, “L”, applied at the bottom of DTCs 1111 to 1118. Suitable control circuits (e.g., Built-In Self-Test or “BIST” circuits in a memory controller die and/or control die(s)) may apply such voltages. Voltage or bias may be measured at one or both ends of a DTC during a test to determine whether a DTC is defective (e.g., by sense amplifiers and/or other circuits that may form part of or be connected to BIST circuits). For example, “L” at lower ends of DTCs 1111 to 1118 may correspond to measurement of voltages to determine if they are low. One or more patterns of test voltages may be applied to DTCs and resulting voltages may be measured to identify defective DTCs or portions of DTCs (e.g., individual defective TSVs and/or bonds between TSVs).

FIG. 11B shows an example of a voltage pattern that may be applied to DTCs (e.g., DTCs 1111 to 1118) or portions of DTCs (e.g., individual TSVs such as A1 to F8) to identify a discontinuous DTC or a discontinuous portion of a DTC. The DTC bias is precharged to a high voltage over a time from t0 to t1 and is then held at the high voltage from time t1 to t2 (e.g., stabilization time). For example, a high voltage, “H”, may be applied at one end of a DTC as shown in FIG. 11A. Subsequently, at time t2, the high voltage is removed and the DTC is allowed to discharge over a discharge period (“t-dis”), which extends from t2 to a detection time, t-det. For example, one end of a DTC may be connected to a terminal with low voltage (e.g., fixed voltage at some low value such as zero volts or ground) as shown in FIG. 11A. The voltage of the DTC may be detected at t-det (e.g., by a sense amplifier). While an electrically continuous DTC may discharge to a low voltage between t2 and t-det (“Continuous”), a discontinuous DTC may remain at high voltage as indicated by the dashed line marked as “Discontinuous.” Thus, comparing voltage at time t-det with a reference voltage (e.g., between Hight and Low) may provide an indicator as to whether a DTC is continuous or discontinuous (open).

In some cases, entire DTCs may be tested for continuity and a discontinuity may cause an entire DTC to be designated as bad (e.g., to be replaced). For example, DTC 1113 may be designated as bad and may be replaced in response to finding a discontinuity. In some cases, portions of a DTC may be individually tested so that some portions of a DTC are designated as bad while other portions of the same DTC may be designated as good (e.g., to be used and not replaced). For example, connections may be provided to enable separate testing of portions of a DTC (e.g., a single TSV or a group of TSVs that forms a subset of the TSVs of a DTC) so that a discontinuity in DTC 1113 that is located in TSV D3 may cause only TSV D3 or some other subset of TSVs (e.g., D3-F3) to be replaced. In some cases, multiple test steps may be performed. For example, a first test step may detect any DTC that includes a discontinuity (e.g., DTC 1113) and a second test step may identify a defective portion (e.g., a specific TSV such as TSV D3 or group of TSVs such as TSVs D3-F3) of any DTC with a discontinuity (e.g., second step may be limited to DTCs that fail the first step such as DTC 1113, while other DTCs such as DTCs 1111 to 1112 and 1114-1118 may not be subject to the second step).

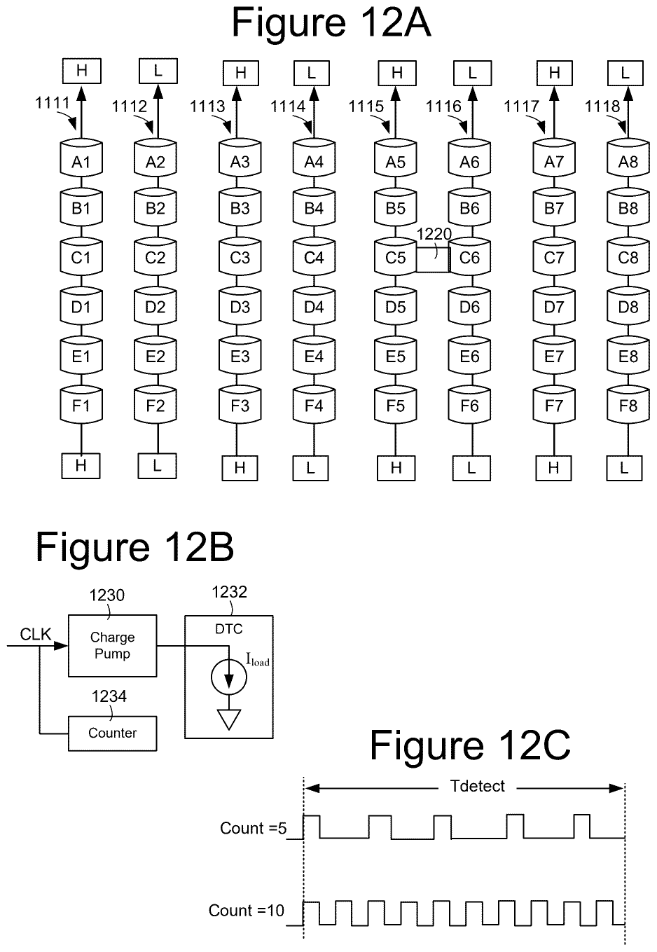

FIGS. 12A-C illustrate an example of detection of short circuited DTCs. As shown in FIG. 12A, DTC 1115 is shorted to DTC 1116 by connection 1220 between TSV C5 and TSV C6. As a result, it may be difficult or impossible to independently control voltage on DTC 1115 and DTC 1116, which may make accessing corresponding portions of a memory system difficult or impossible. FIG. 12A shows high (“H”) and low (“L”) voltages applied on alternating DTCs (e.g., high voltage on odd numbered DTCs 1111, 1113 1115 and 1117 and low voltage on even numbered DTCs 1112, 1114, 1116 and 1118). In an example, current needed to maintain a DTC at a high voltage may be used as an indicator of a short. For example, current required to maintain DTC 1115 or a portion of DTC 1115 at a high voltage may indicate whether there is a significant leakage current (e.g., to an adjacent DTC that is at low voltage such as DTC 1116). A range of acceptable leakage current may be found by experimentation and a leakage current outside of the acceptable range may indicate a shorted DTC. Where adjacent DTCs are found to have leakage current outside of the acceptable range, it may be taken as an indication that the DTCs are shorted (electrically connected). In response, both DTCs or portions thereof may be marked as bad and may be replaced. For example, inverting the test pattern of FIG. 12A so that DTC 1115 receives low voltage and DTC 1116 receives high voltage may show a large current is needed to maintain the high voltage on DTC 1116, which indicates a significant leakage current. Because neighboring DTCs 1115 and 1116 have significant leakage current, they may be designated as bad and replaced or identified bad portions (e.g., TSVs C5 and C6) may be designated as bad and replaced.

FIG. 12B shows an example of a circuit that may be used to carry out testing as illustrated in FIG. 12A. A clock signal, CLK, is received by a charge pump 1230, which provides a current to DTC 1232 to maintain it at a high voltage. For example, CLK may be used as a switching signal to trigger switching of one or more switching stage of charge pump 1230 and may be controlled by feedback from the output of charge pump 1230 to maintain a target voltage. Each switching cycle may transfer a predetermined amount of charge so that the total charge transferred in a given time period is proportional to the number of clock pulses and to the amount of charge per clock pulse (e.g., Charge=(#CLK)*(charge/CLK). DTC 1232 is shown as a current source that sinks a current, I_{load}, provided by charge pump 1230. If I_{load} is above a predetermined limit, it may indicate significant leakage current (e.g., caused by a short to another component such as a neighboring DTC). Counter 1234 receives CLK and may count clock pulses within a time period, which may be used as an indicator of I_{load}.

Because current output of charge pump 1230 is proportional to the number of clock pulses, excessive current, I_{load} for a given DTC or portion thereof may be found from a corresponding number of clock pulses. FIG. 12C shows an example of operation of counter 1234. In the upper plot, five clock pulses occur within a detection time, Tdetect (“count=5”). In the lower plot, ten clock pulses occur within the detection time (“count=10”). This difference may indicate different I_{load} values and leakage currents. For example, an acceptable current range for I_{load} may be found and a corresponding range for CLK count may be obtained (e.g., fewer than eight cycles within Tdetect). A clock cycle count within the range (e.g., count=5) indicates acceptable leakage current while a count outside the range (e.g., count=10) indicates excessive leakage current. As a result of excessive leakage current the corresponding DTC or portion thereof may be designated as bad and may be replaced.

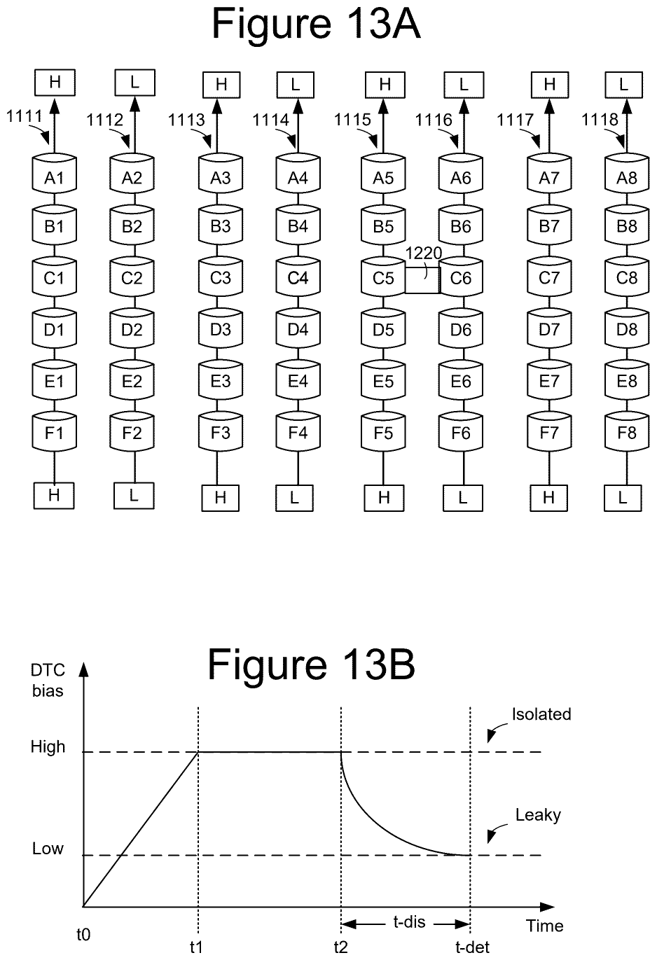

FIGS. 13A-B illustrate another example of a scheme to test DTCs or portions thereof that may be shorted. In FIG. 13A, high and low voltages are applied on alternating DTCs. For example, odd numbered DTCS 1111, 1113, 1115 and 1117 are connected to a high voltage while even numbered DTCs 1112, 1114, 1116 and 1118 are connected to a low voltage. FIG. 13B shows an example of a voltage signal that may be applied on set of DTCs (e.g., odd numbered DTCs during testing) or a portion thereof (e.g., an individual TSV of a DTC). The voltage signal is similar to that of FIG. 11B. The DTC bias is precharged to a high voltage over a time from t0 to t1 and is then held at the high voltage from time t1 to t2 (e.g., stabilization time). For example, a high voltage, “H”, may be applied at one or both ends of a DTC as shown in FIG. 13A. Subsequently, at time t2, the high voltage is removed and the DTC is allowed to discharge over a discharge period (“t-dis”), which extends from t2 to a detection time, t-det (e.g., DTCs may be electrically isolated or floating during t-dis). The voltage of the DTC may be detected at t-det (e.g., by a sense amplifier). While an electrically isolated DTC may remain at a high voltage between t2 and t-det because it is adequately isolated (“Isolated”), voltage of a DTC that is insufficiently isolated may drop from the high voltage to a low voltage due to leakage current with a neighboring DTC (“Leaky”). By monitoring discharge of DTCs at high voltage (odd numbered DTCs) defective odd numbered DTCs may be identified. Subsequently even numbered defective DTCs may be identified by charging them while odd numbered DTCs remain at fixed low voltage (e.g., test pattern is inverted).

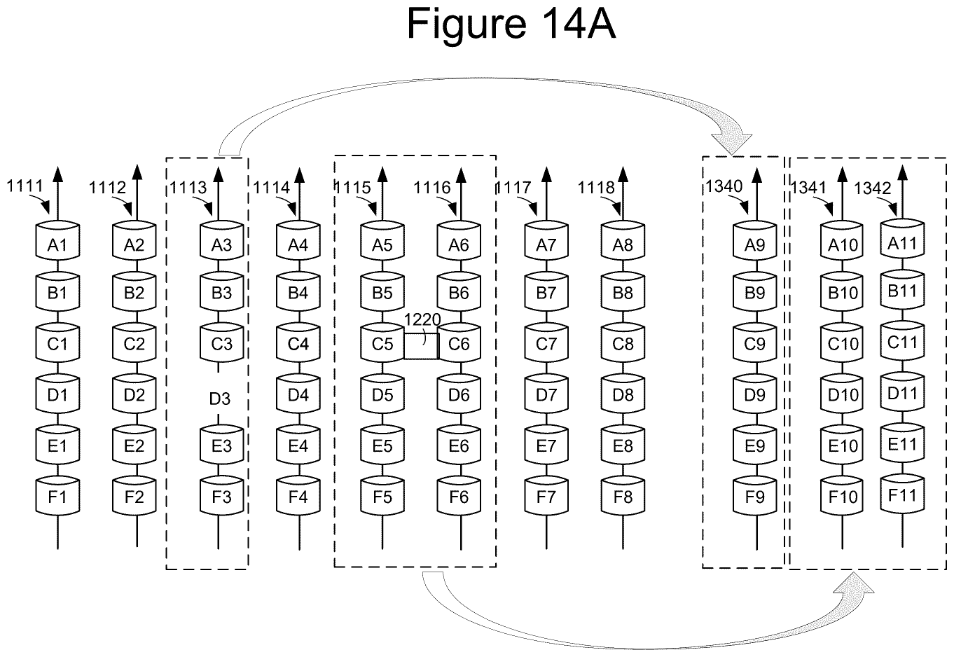

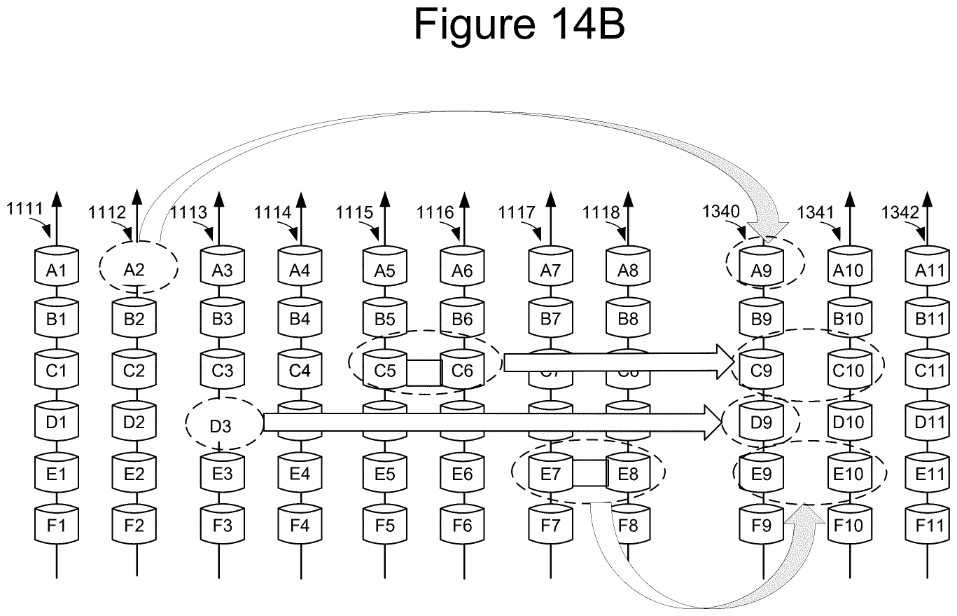

FIG. 14A illustrates an example of DTCs that includes, in addition to DTCs 1111 to 1118, redundant DTCs 1340 to 1342, which may be used for replacement of defective DTCs. In the example of FIG. 14A, DTC 1113 is identified as defective (e.g., open or discontinuous) as discussed with respect to FIGS. 11A-B and DTCs 1115 and 1116 are identified as defective (e.g., shorted or electrically connected) as discussed with respect to FIGS. 12A-C. In response, defective DTCs 1113, 1115 and 1116 are replaced by redundant DTCs 1340, 1341 and 1342 respectively. As a result of this replacement, signals that would otherwise have been sent via DTCs 1113, 1115 and 1116 are instead sent via redundant DTCs 1340, 1341 and 1342 respectively.

While remapping an entire DTC may provide a simple way to address defective DTCs, in some cases, portions of a DTC may be remapped or replaced while other portions of the same DTC remain in use, which may make more efficient use of available redundant DTCs.

FIG. 14B illustrates an alternative remapping scheme in which individual defective TSVs may be replaced with redundant TSVs. For example, defective TSV D3 in DTC 1113 is replaced with redundant TSV D9, while other TSVs of DTC 1113 (TSVs A3-C3 and E3-F3) remain in use and defective TSVs C5 and C6 in DTCs 1115 and 1116 are replaced with redundant TSVs C9 and C10 while other TSVs in DTCs 1115 and 1116 remain in use. The scheme of FIG. 14B may enable operation with a larger number of defects because each redundant DTC may be used to provide multiple replacement TSVs to overcome multiple defects. For example, FIG. 14B shows replacement of defective TSVs A2, E7 and E8 in addition to defective TSVs D3, C5 and C6 using different redundant TSVs (A9, E9 and E10) in the same redundant DTCs (1340 and 1341). Thus, a larger number of defects are overcome using a smaller number of redundant DTCs than in the example of FIG. 14A. Additional defects may be overcome using additional redundant TSVs and/or redundant DTCs. For example, where a DTC includes more than a predetermined number of defective TSVs, the DTC may be replaced by a redundant DTC (e.g., redundant DTC 1342 may be used to replace an entire DTC).

While the examples of FIGS. 14A and 14B show replacement of an entire DTC or a single TSV in a DTC, defective portions of a DTC of various sizes may be replaced and the unit of replacement or remapping is not limited to the examples of an entire DTC (FIG. 14A) or a single TSV (FIG. 14B). For example, TSVs of two neighboring dies may be replaced together as a unit (e.g., memory die and control die of an integrated memory assembly), TSVs of four neighboring dies may be replaced together as a unit (e.g., two memory dies and two control dies of a mirrored die pair) and/or other units of replacement/remapping may be used.

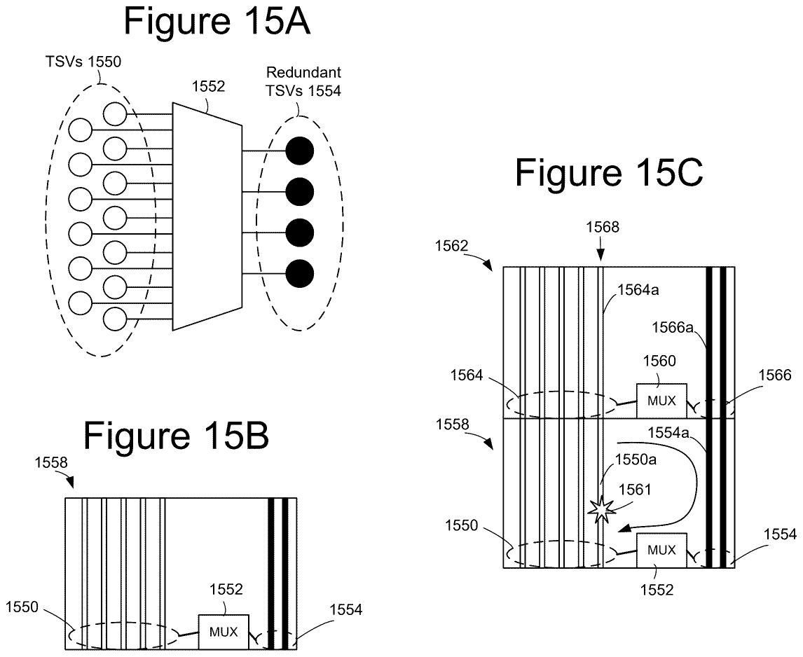

FIGS. 15A-C illustrate examples of control circuits for testing and remapping of TSVs in a stack. FIG. 15A illustrates TSVs 1550 (e.g., TSVs 1111-1118) connected to a multiplexer/demultiplexer circuit 1552 (mux), which is connected to redundant TSVs 1554 (e.g., 1340-1342). Similar multiplexer/demultiplexer circuits may be provided in dies in a stack of dies (e.g., in control dies and/or memory dies in a stack of integrated memory assemblies such as stack 860). Mux 1552 may allow any individual one of TSVs 1550 to be electrically connected to any one of redundant TSVs 1554. Mux 1552 (and similar multiplexer/demultiplexer circuits) may be provided at various levels in a stack and may be controlled by logic circuits (e.g., in a control die and/or memory controller) to perform testing and/or replacement (e.g., to identify and replace defective TSVs). While mux 1552 is shown as a single unit, separate multiplexer and demultiplexer functionality may be implemented by separate multiplexer and demultiplexer circuits. A signal may be sent from a TSV of TSVs 1550 to a redundant TSV of redundant TSVs 1554 through mux 1552 and also from a redundant TSV of redundant TSVs 1554 to a TSV of TSVs 1550. While TSVs 1550 and redundant TSVs 1554 are shows as distinct groups, redundancy may be provided in various ways and redundant TSVs are not necessarily different or physically separated from other TSVs.

FIG. 15B shows a cross sectional view of a die 1558 (e.g., memory die, control die or memory controller die), which includes TSVs 1550 and redundant TSVs 1554 connected by mux 1552. In this example, mux 1552 is connected close to the lower surface of die (e.g., connected to bond pads or close to bond pads that are bonded to a neighboring die) while in other examples, connections may be made at other locations (e.g., at or near the upper surface or at some mid-point between surfaces). In example, a mux, such as mux 1552 is placed locally in CMOS logic circuits of each control die that is bonded to a memory die to form an integrated memory assembly (e.g., in a cmos-bonded-array wafer) in a stack of such integrated memory assemblies (e.g., stack 860 of FIGS. 8A-B). In yet another example, a mux such as mux 1552 is placed globally in each die of a controller wafer so that each memory controller die can allocate signals to DTCs (e.g., as illustrated in FIG. 10).

FIG. 15C shows operation of mux 1552 during testing and replacement. FIG. 15C shows a portion of a stack that includes two dies, dies 1558 and 1562. Die 1562 includes TSVs 1564, which are bonded to TSVs 1550 of die 1558 and redundant TSVs 1566, which are bonded to redundant TSVs 1554 of die 1558. TSVs 1564 are connected to redundant TSVs 1556 by mux 1560, which may be similar to mux 1552. During testing, remapping may be performed to bypass TSV 1550a (e.g., in response to determining that DTC 1568 is not electrically continuous due to defect 1561). For example, mux 1560 may be configured to connect TSV 1564a with redundant TSV 1566a in die 1562 and mux 1552 may be configured to connect redundant TSV 1554a (which is bonded to redundant TSV 1566a) with TSV 1550a in die 1558. In this way, a signal (e.g., control, data, address, supply or other signal) that is sent via DTC 1568 is routed around TSV 1550a as illustrated by the arrow. During testing, a signal may be remapped around portions of a DTC (e.g., around one or more TSVs) that is not electrically continuous to identify the location of a defect (e.g., discontinuity). When remapping around a portion of a DTC is successful (e.g., results in reconnection of two parts of a DTC that are isolated by a defect), the remapping may be used to replace the portion during subsequent operation. For example, in response to determining that remapping as shown in FIG. 15C provides electrical continuity along DTC 1568, the same remapping may be used to replace defective TSV 1550a (e.g., by configuring control circuits to control mux 1560 and mux 1552 to make the connections shown).

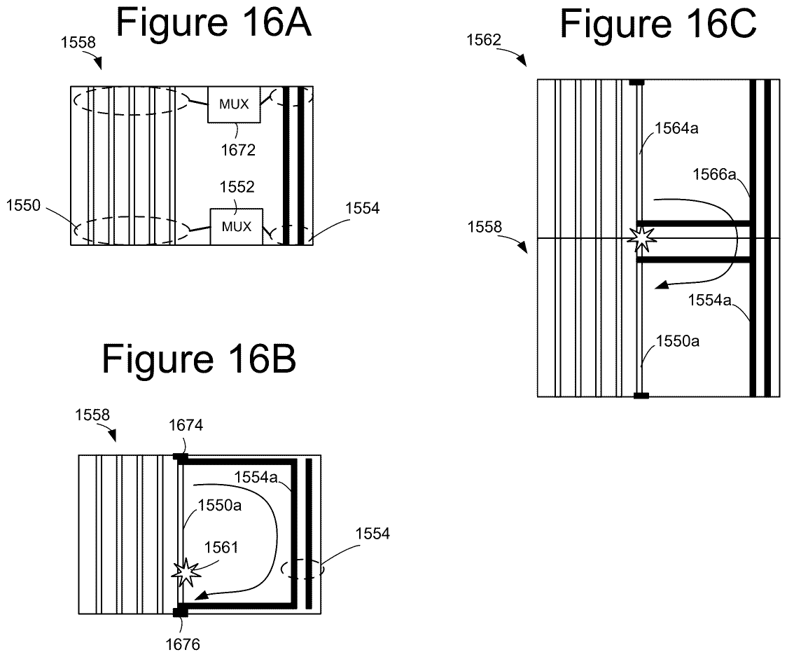

FIGS. 16A-C show another example in which multiplexer/demultiplexer circuits are provided at or near top and bottom surfaces of a die or assembly of dies. For example, FIG. 16A shows an example in which die 1558 includes multiplexer/demultiplexer circuits 1672 connecting TSVs 1550 and redundant TSVs 1554 in addition to mux 1552. Mux 1672 is connected close to the upper surface of die 1558 (e.g., connected to bond pads).

FIG. 16B shows how the arrangement of FIG. 16A allows remapping of a signal around defect 1561. For example, top bond pad 1674 of TSV 1550a is connected to redundant TSV 1554a (e.g., by mux 1672) and lower bond pad 1676 of TSV 1550a is connected to redundant TSV 1554a (e.g., by mux 1552) so that TSV 1550a is bypassed with top and bottom pads 1674 and 1676 connected by redundant TSV 1554a to allow a signal to pass between top and bottom bond pads as shown. In the example shown, redundant TSVs 1554 are not connected to bond pads on the surface of die 1558. For example, redundant TSVs may only be connected through multiplexer/demultiplexer circuits. This may allow remapping within an individual die.

In addition to defects that may occur in TSVs, some defects may occur at interfaces between dies where TSVs of one die are bonded to TSVs of another die. A configuration such as illustrated in FIG. 16A may be used to overcome such defects. FIG. 16C shows an example in which remapping is performed to route a signal around a defect that occurs at an interface between dies 1558 and 1562 (e.g., dies each having upper and lower multiplexer/demultiplexer circuits as illustrated in FIG. 16A). In this example, TSV 1564a is connected to redundant TSV 1566a in die 1562 and TSV 1550a is connected to redundant TSV 1554a in die 1558. In this example, redundant TSVs 1566a and 1554a are bonded together (unlike in FIG. 16B).

In another configuration shown in FIG. 16D a direct connection 1680 may be provided to bypass a bad bond. For example, multiplexer/demultiplexer circuits 1552 and 1672 may connect to redundant bond pads that are not connected to TSVs. This allows multiplexer/demultiplexer circuits to remap a signal through a pair of redundant bond pads (e.g., direct connection 1660 may be formed by a pair of redundant bond pads that are connected to respective multiplexer/demultiplexer circuits), which may bypass a defect located where TSVs are bonded.

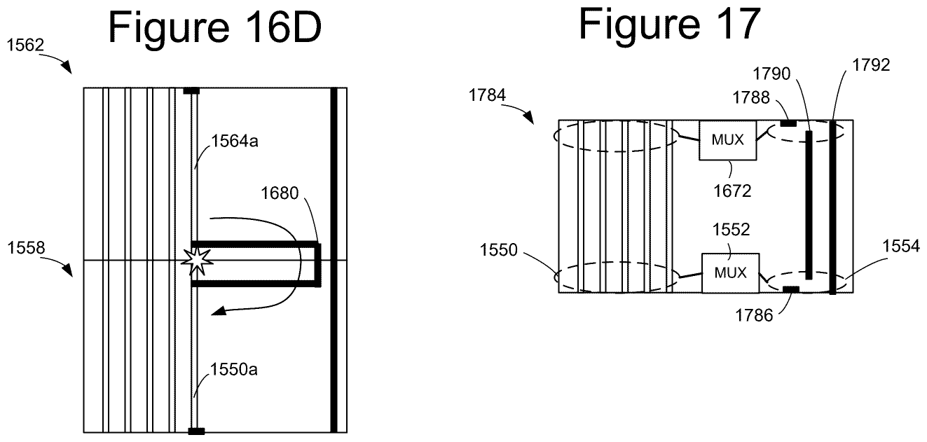

In some cases, multiplexer/demultiplexer circuits in a die may be connected to TSVs and/or other electrical conductors that may be used to perform remapping. For example, FIG. 17 shows die 1784 including mux 1552, which connects TSVs 1550 with a redundant bond pad 1786 for connection as shown in FIG. 16D, with a redundant TSV 1790 that does not connect with a bond pad for connection as shown in FIG. 16B and with a redundant TSV 1792, which connects with bond pads for connection with neighboring dies. Similarly, mux 1672 connects TSVs 1550 with a redundant bond pad 1788, redundant TSV 1790 and redundant TSV 1792. In this configuration, remapping may be used to replace an entire DTC, one or more TSV and one or more connection between TSVs of neighboring dies.

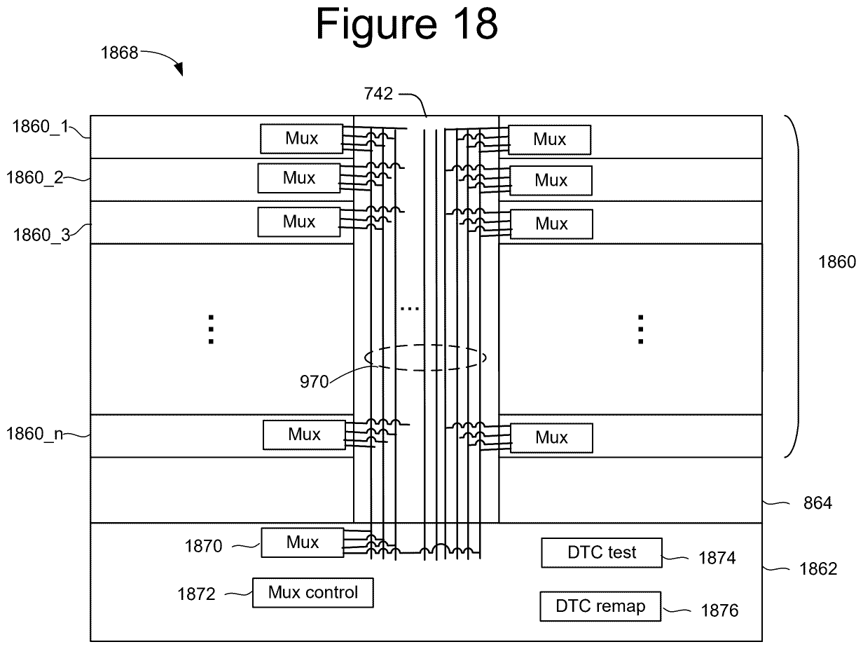

FIG. 18 shows an example of a storage system 1868, which includes a stack 1860 of dies (e.g., control dies and memory dies that are bonded to form integrated memory assemblies, which may be combined as mirrored die pairs). Stack 1860 includes dies 1860_1 to 1860_n, each of which includes multiplexer/demultiplexer circuits, “Mux”, which are connected to DTCs 970 (including redundant DTCs), which extend through DTC region 742. While two multiplexer/demultiplexer circuits are shown in each die in this example, the number of such circuits may be any suitable number (e.g., each channel in a die may have dedicated multiplexer/demultiplexer circuits or common multiplexer/demultiplexer circuits may serve all channels of a die). In some cases, multiplexer/demultiplexer circuits are only provided in control dies (not in memory dies) or in some other arrangement.

FIG. 18 shows controller die 1862, which may include logic circuits configured to access memory cells in stack 1860 (e.g., some or all circuits of memory controller 120). Controller die includes multiplexer/demultiplexer circuits 1870 and also includes multiplexer/demultiplexer control circuits 1872 (“Mux control” circuits). Mux control circuits 1872 may control multiplexer/demultiplexer circuits 1870 and multiplexer/demultiplexer circuits in stack 1860. For example, mux control circuits 1872 may be configured to send signals to control multiplexer/demultiplexer circuits to remap DTCs and/or portions of DTCs (e.g., TSVs) to carry out testing and/or to bypass DTC defects (e.g., as described in any of the examples of testing and remapping).

Controller die 1862 also includes DTC test circuits 1874, which may be configured to perform testing of DTCs 970 (e.g., in conjunction with mux circuits 1870 and mux control circuits 1872). For example, DTC test circuits 1874 may include or be in communication with a memory that has one or more test schemes (e.g., test patterns) and DTC circuits may access such a test scheme and implement the test scheme by causing application of appropriate voltage pattern(s) on DTCs 970 and causing mux control circuits 1872 to control multiplexer/demultiplexer circuits. DTC test circuits 1874 may identify one or more defective DTC in DTCs 970 and may record any such DTCs.

Controller die 1862 also includes DTC remapping circuit 1876, which may be configured to remap DTCs (e.g., entire DTCs and/or portions of DTCs) according to test results obtained by DTC test circuits 1874. For example, DTC remapping circuit 1876 may cause remapping that replaces a defective DTC identified by DTC test circuits 1874 with a redundant DTC, replaces a defective portion of a DTC (e.g., one or more TSV) with a portion of a redundant DTC (e.g., one or more redundant TSVs) and/or replaces a defective connection between TSVs with a redundant connection. DTC test circuits 1874 and DTC remapping circuits 1876 (e.g., alone or in combination with one or more multiplexer/demultiplexer circuits and/or mux control circuits 1872) may be considered an example of means for detecting one or more defective DTCs of the plurality of DTCs and replacing at least portions of the one or more defective DTCs by at least portions of redundant DTCs.

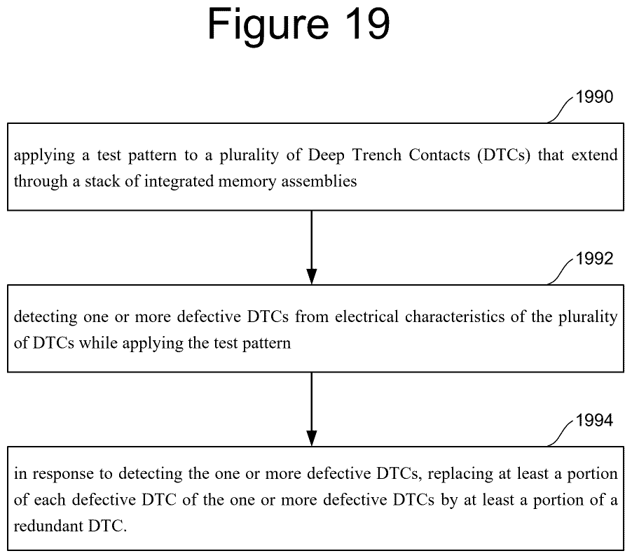

FIG. 19 shows an example of a method that includes applying a test pattern to a plurality of Deep Trench Contacts (DTCs) that extend through a stack of integrated memory assemblies 1990 (e.g., applying high voltage on one or more DTCs such as odd/even DTCs) detecting one or more defective DTCs from electrical characteristics of the plurality of DTCs while applying the test pattern 1192 (detecting voltage after a supply is switched off as illustrated in FIGS. 11B and 13B or detecting a charge pump switching clock frequency above a threshold as illustrated in FIG. 12C). The method further includes, in response to detecting the one or more defective DTCs, replacing at least a portion of each defective DTC of the one or more defective DTCs by at least a portion of a redundant DTC 1994 (e.g., as illustrated in FIGS. 14A-B).

According to an example, an apparatus includes control circuits configured to connect to stacked integrated memory assemblies through Deep Trench Contacts (DTCs) that extend through the stacked integrated memory assemblies. Each integrated memory assembly is formed of a memory die that is bonded to a control die. The control circuits are configured to apply a test pattern to the DTCs to detect defects in the DTCs.

In one or more embodiments, the control circuits are configured to apply the test pattern by charging and discharging the plurality of DTCs and to detect defects by identifying DTCs that fail to discharge.

In one or more embodiments, the control circuits are configured to apply the test pattern by charging a first group of DTCs to a test voltage using a charge pump, maintaining a second group of DTCs at a fixed voltage and to detect defects from a characteristic of the charge pump.

In one or more embodiments, the characteristic of the charge pump is a frequency of a switching signal that is used to switch one or more switching stage of the charge pump.

In one or more embodiments, the control circuits are configured to apply the test pattern by charging a first group of DTCs to a test voltage, maintaining a second group of DTCs at a fixed voltage and to detect defects from change in the test voltage over time.

In one or more embodiments, the control circuits are located in a memory controller die located under the stacked integrated memory assemblies.

In one or more embodiments, the apparatus further includes multiplexer/demultiplexer circuits located in control dies of the plurality of stacked integrated memory assemblies, the multiplexer/demultiplexer circuits configured to remap signals through the plurality of DTCs.

In one or more embodiments, the plurality of DTCs includes one or more redundant DTCs and the control circuits are further configured to replace one or more defective DTC with one or more redundant DTC using the multiplexer and demultiplexer circuits of one or more integrated memory assembly.

In one or more embodiments, the control circuits are configured to replace a defective DTC with a redundant DTC in response to determining that the defective DTC includes a discontinuity.

In one or more embodiments, the control circuits are configured to replace a pair of defective DTCs with a pair of redundant DTCs in response to determining that the pair of defective DTCs are electrically connected.

In one or more embodiments, the plurality of stacked integrated memory assemblies are arranged in mirrored die pairs such that orientation of even numbered integrated memory assemblies is opposite to orientation of odd numbered integrated memory assemblies.

An example of a method includes applying a test pattern to a plurality of Deep Trench Contacts (DTCs) that extend through a stack of integrated memory assemblies; detecting one or more defective DTCs from electrical characteristics of the plurality of DTCs while applying the test pattern; and in response to detecting the one or more defective DTCs, replacing at least a portion of each defective DTC of the one or more defective DTCs by at least a portion of a redundant DTC.

In one or more embodiments, applying the test pattern includes charging the plurality of DTCs to a predetermined voltage and subsequently discharging the plurality of DTCs from the predetermined voltage, and wherein the one or more defective DTCs are detected from failure of the one or more defective DTCs to discharge adequately in a discharge period.

In one or more embodiments, applying the test pattern includes charging a first group of DTCs to a test voltage using a charge pump while maintaining a second group of DTCs at a fixed voltage and the one or more defective DTCs are from a characteristic of the charge pump while maintaining the first group of DTCs at the test voltage using the charge pump.

In one or more embodiments, applying the test pattern includes charging a first group of DTCs to a test voltage and subsequently floating the first group of DTCs while maintaining a second group of DTCs at a fixed voltage and wherein detecting the one or more defective DTCs includes monitoring discharge of the first group of DTCs.

In one or more embodiments, replacing at least a portion of a defective DTC includes routing a signal from a first portion of the defective DTC through a multiplexer to a redundant DTC and from the redundant DTC through a demultiplexer to a second portion of the defective DTC.

In one or more embodiments, the method further includes in response to detecting a first defective DTC and a second defective DTC that are electrically connected by a defect, replacing the first defective DTC by a first redundant DTC and replacing the second defective DTC by a second redundant DTC.

An example of a storage system includes a stack of mirrored die pairs, each mirrored die pair including a first control die bonded to a first memory die, a second control die bonded to a second memory die and the first memory die bonded to the second memory die; a memory controller die that includes logic circuits configured to access memory cells in the stack of mirrored die pairs; a plurality of Deep Trench Contacts (DTCs) that extend through the stack of mirrored die to connect the memory controller die with each mirrored die pair, the plurality of DTCs including one or more redundant DTCs; and means for detecting one or more defective DTCs of the plurality of DTCs and replacing at least portions of the one or more defective DTCs by at least portions of redundant DTCs.

In one or more embodiments, the first and second memory dies include 3D NAND memory structures.

In one or more embodiments, each mirrored die pair includes multiplexer/demultiplexer circuits connected to the plurality of DTCs, the multiplexer/demultiplexer circuits controlled by the logic circuits in the memory controller die.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more other parts). In some cases, when an element is referred to as being connected or coupled to another element, the element may be directly connected to the other element or indirectly connected to the other element via one or more intervening elements. When an element is referred to as being directly connected to another element, then there are no intervening elements between the element and the other element. Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects, but may instead be used for identification purposes to identify different objects.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

What is claimed is:

1. An apparatus comprising:
control circuits configured to connect to a plurality of stacked integrated memory assemblies through a plurality of Deep Trench Contacts (DTCs) that extend through the stacked integrated memory assemblies, each integrated memory assembly formed of a memory die that is bonded to a control die, and to apply a test pattern to the plurality of DTCs to detect defects in the plurality of DTCs.

2. The apparatus of claim 1, wherein the control circuits are configured to apply the test pattern by charging and discharging the plurality of DTCs and to detect defects by identifying DTCs that fail to discharge.

3. The apparatus of claim 1, wherein the control circuits are configured to apply the test pattern by charging a first group of DTCs to a test voltage using a charge pump, maintaining a second group of DTCs at a fixed voltage and to detect defects from a characteristic of the charge pump.

4. The apparatus of claim 3, wherein the characteristic of the charge pump is a frequency of a switching signal that is used to switch one or more switching stage of the charge pump.

5. The apparatus of claim 1, wherein the control circuits are configured to apply the test pattern by charging a first group of DTCs to a test voltage, maintaining a second group of DTCs at a fixed voltage and to detect defects from change in the test voltage over time.

6. The apparatus of claim 1, wherein the control circuits are located in a memory controller die located under the stacked integrated memory assemblies.

7. The apparatus of claim 6, further comprising multiplexer/demultiplexer circuits located in control dies of the plurality of stacked integrated memory assemblies, the multiplexer/demultiplexer circuits configured to remap signals through the plurality of DTCs.

8. The apparatus of claim 7, wherein the plurality of DTCs includes one or more redundant DTCs and the control circuits are further configured to replace one or more defective DTC with one or more redundant DTC using the multiplexer and demultiplexer circuits of one or more integrated memory assembly.

9. The apparatus of claim 8, wherein the control circuits are configured to replace a defective DTC with a redundant DTC in response to determining that the defective DTC includes a discontinuity.

10. The apparatus of claim 8, wherein the control circuits are configured to replace a pair of defective DTCs with a pair of redundant DTCs in response to determining that the pair of defective DTCs are electrically connected.

11. The apparatus of claim 1, wherein the plurality of stacked integrated memory assemblies are arranged in mirrored die pairs such that orientation of even numbered integrated memory assemblies is opposite to orientation of odd numbered integrated memory assemblies.

12. A method comprising:
applying a test pattern to a plurality of Deep Trench Contacts (DTCs) that extend through a stack of integrated memory assemblies;
detecting one or more defective DTCs from electrical characteristics of the plurality of DTCs while applying the test pattern; and
in response to detecting the one or more defective DTCs, replacing at least a portion of each defective DTC of the one or more defective DTCs by at least a portion of a redundant DTC.

13. The method of claim 12, wherein applying the test pattern includes charging the plurality of DTCs to a predetermined voltage and subsequently discharging the plurality of DTCs from the predetermined voltage, and wherein the one or more defective DTCs are detected from failure of the one or more defective DTCs to discharge adequately in a discharge period.

14. The method of claim 12, wherein applying the test pattern includes charging a first group of DTCs to a test voltage using a charge pump while maintaining a second group of DTCs at a fixed voltage and the one or more defective DTCs are from a characteristic of the charge pump while maintaining the first group of DTCs at the test voltage using the charge pump.

15. The method of claim 12, wherein applying the test pattern includes charging a first group of DTCs to a test voltage and subsequently floating the first group of DTCs while maintaining a second group of DTCs at a fixed voltage and wherein detecting the one or more defective DTCs includes monitoring discharge of the first group of DTCs.

16. The method of claim 12, wherein replacing at least a portion of a defective DTC includes routing a signal from a first portion of the defective DTC through a multiplexer to a redundant DTC and from the redundant DTC through a demultiplexer to a second portion of the defective DTC.

17. The method of claim 12, further comprising:
in response to detecting a first defective DTC and a second defective DTC that are electrically connected by a defect, replacing the first defective DTC by a first redundant DTC and replacing the second defective DTC by a second redundant DTC.

18. A storage system, comprising:
a stack of mirrored die pairs, each mirrored die pair including a first control die bonded to a first memory die, a second control die bonded to a second memory die and the first memory die bonded to the second memory die;
a memory controller die that includes logic circuits configured to access memory cells in the stack of mirrored die pairs;
a plurality of Deep Trench Contacts (DTCs) that extend through the stack of mirrored die to connect the memory controller die with each mirrored die pair, the plurality of DTCs including one or more redundant DTCs; and
means for detecting one or more defective DTCs of the plurality of DTCs and replacing at least portions of the one or more defective DTCs by at least portions of redundant DTCs.

19. The storage system of claim 18, wherein the first and second memory dies include 3D NAND memory structures.

20. The storage system of claim 18, wherein each mirrored die pair includes multiplexer/demultiplexer circuits connected to the plurality of DTCs, the multiplexer/demultiplexer circuits controlled by the logic circuits in the memory controller die.
